(19) United States
(12) Patent Application Publication
(10) Pub. No.: US 2011/0057210 A1
(43) Pub. Date: Mar. 10, 2011

(54) ORGANIC ELECTROLUMINESCENCE DEVICE AND METHOD FOR PRODUCING THE SAME

(76) Inventors: Shinichiro SONODA, Ashigarakami-gun (JP); Manabu Tobisc, Ashigarakami-gun (JP)

(21) Appl. No.: 12/874,286

(22) Filed: Sep. 2, 2010

(30) Foreign Application Priority Data
Sep. 10, 2009 (JP) 2009-209684

(51) Int. Cl. H01L 51/52; H01L 33/60

(52) U.S. Cl. 257/88; 438/29; 257/E51.018; 257/E33.073

(57) ABSTRACT

To provide an organic electroluminescence device including: a plurality of organic electroluminescence display portions, each of which includes at least an anode, a light-emitting layer and a cathode; a plurality of lenses which are placed over the organic electroluminescence display portions, and each of which controls an optical path of light emitted from the light-emitting layer; and a plurality of filter layers, each of which is formed integrally with each lens and placed so as to cover the optical path in each lens, and transmits the light emitted from the light-emitting layer, wherein the filter layer formed integrally with one lens among the lenses absorbs at least light with a peak wavelength among light which has passed through at least one of lenses that are adjacent to the one lens.

### BACKGROUND OF THE INVENTION

1. Field of the Invention

The present invention relates to an organic electroluminescence device (hereinafter referred to also as “organic EL device”) and a method for producing the organic electroluminescence device.

2. Description of the Related Art

The organic EL device (organic electroluminescence device) is a self-light-emitting display device and is used for display, lighting, etc. The organic EL display has advantages in terms of display performance, such as high visibility and less viewing angle dependence, in comparison with conventional CRTs or LCDs.

Also, it has such advantages that the display can be reduced in weight and thickness. As well as having advantages in terms of reduction in weight and thickness, the organic EL lighting has the potential to realize lighting in a heretofore unrealizable form by the use of a flexible substrate.

As just described, the organic EL device has excellent characteristics. However, in general, the refractive indices of layers constituting the display device, including a light-emitting layer, are higher than the refractive index of air. For example, in the organic EL device, the refractive index of a thin organic layer such as a light-emitting layer is in the range of 1.6 to 2.1. Thus, emitted light is liable to be totally reflected at the interface, and the light extraction efficiency is less than 20%, which means that most of the light is lost.

For example, an organic EL display portion in a generally known organic EL device includes a substrate and also includes, over this substrate, a pair of electrode layers and organic compound layer(s) placed between the electrode layers. The organic compound layer(s) include(s) a light-emitting layer, and the organic EL device allows light emitted by the light-emitting layer to discharge from the light extraction surface side. In this case, it is impossible to extract totally reflected light components (which are light components reflected at a critical angle or greater) at the light extraction surface or at the interface between the electrode layer and the organic compound layer, so that there is a problem of low light extraction efficiency.

Accordingly, to improve light extraction efficiency, there has been proposed a variety of organic EL devices wherein an optical path of light emitted by a light-emitting layer is controlled, and a light-extracting member (such as a lens) which allows the light emitted by the light-emitting layer to discharge from the light extraction surface side is placed over the optical path.

Japanese Patent Application Laid-Open (JP-A) No. 2003-272873 proposes an organic EL head including a substrate, a reflective layer formed on the substrate, an anode formed on the reflective layer, an organic EL light-emitting layer formed on the anode, and a cathode formed of a thin metal film (with a thickness that allows light to pass through the film), one surface of which is attached to the light-emitting layer and the other surface of which is covered with a semitransparent reflective layer, wherein the reflective layer and the semitransparent reflective layer constitute a micro-optical resonator (microcavity), and a lens is formed on the outside of the semitransparent reflective layer.

This proposal uses the organic EL head as a writing unit of an image forming apparatus.

JP-A No. 2004-227940 proposes a display including electrodes, a light-emitting element placed between the electrodes, a light-emitting layer which allows the light-emitting element to emit light upon application of voltage between the electrodes, and a lens layer that has at least one lens formed in a position (within the length of one side of the light-emitting element) over the electrode with respect to the light emission direction in which the light emitted from the light-emitting element is output, wherein the lens has a diameter greater than that of the light-emitting element.

JP-A No. 2007-529863 proposes a transparent base material comprising a plurality of continuous hemispherical convex portions (lenses) having a diameter of 25 nm to 1,000 nm, formed on its first main surface; and an organic light-emitting element comprising a substrate, a first electrode, an organic material layer and a second electrode, wherein a plurality of continuous hemispherical convex portions (lenses) having a diameter of 25 nm to 1,000 nm are provided over the substrate's lower surface that is not in contact with the first electrode and/or over the second electrode's upper surface that is not in contact with the organic material layer.

In these conventional techniques, however, entry of light, which has discharged from a lens, into another lens adjacent to the foregoing lens causes a problem in which light is waveguided between a light-emitting layer and lenses and thus image bleeding and/or image blurring arise(s).

### BRIEF SUMMARY OF THE INVENTION

The present invention solves the problems in related art and provides an organic electroluminescence device which does not cause image blurring, which has high light extraction efficiency (front luminance) and which makes it possible to reduce electricity consumption; and a method for producing the organic electroluminescence device.

Means for solving the problems are as follows.

<1> An organic electroluminescence device including:

a plurality of organic electroluminescence display portions, each of which includes at least an anode, a light-emitting layer and a cathode;

a plurality of lenses which are placed over the organic electroluminescence display portions, and each of which controls an optical path of light emitted from the light-emitting layer; and

a plurality of filter layers, each of which is formed integrally with each lens and placed so as to cover the optical path in each lens, and transmits the light emitted from the light-emitting layer,

wherein the filter layer formed integrally with one lens among the lenses absorbs at least light with a peak wavelength among light which has passed through at least one of lenses that are adjacent to the one lens.

<2> The organic electroluminescence device according to <1>, wherein the filter layer formed integrally with the one lens among the lenses absorbs at least lights with peak wavelengths among lights which have passed through lenses aligned in at least two directions among the lenses that are adjacent to the one lens.
<3> The organic electroluminescence device according to <2>, wherein the filter layer formed integrally with the one lens among the lenses absorbs at least lights with peak wavelengths among lights which have passed through lenses aligned in at least three directions among the lenses that are adjacent to the one lens.
<4> The organic electroluminescence device according to <1>, wherein the filter layer formed integrally with the one lens among the lenses absorbs at least lights with peak wavelengths among lights which have passed through all the lenses that are adjacent to the one lens.
<5> The organic electroluminescence device according to any one of <1> to <4>, wherein the one lens functions as the filter layer.
<6> The organic electroluminescence device according to any one of <1> to <4>, wherein each filter layer is formed at an interface of each lens on the side of the light-emitting layer.
<7> The organic electroluminescence device according to any one of <1> to <4>, wherein each filter layer is formed so as to cover a surface of each lens.
<8> The organic electroluminescence device according to any one of <1> to <7>, further including a plurality of pixel elements each having a plurality of the organic electroluminescence display portions including the light-emitting layers which emit light of the same color,

wherein the light-emitting layers of the organic electroluminescence display portions in one pixel element among the pixel elements emit light whose color is different from the color of light emitted by the light-emitting layers of the organic electroluminescence display portions in at least one of pixel elements that are adjacent to the one pixel element.

<9> The organic electroluminescence device according to <8>, wherein the light-emitting layers of the organic electroluminescence display portions in the one pixel element among the pixel elements emit light whose color is different from the colors of lights emitted by the light-emitting layers of the organic electroluminescence display portions in the pixel elements that are adjacent to the one pixel element.
<10> A method for producing the organic electroluminescence device according to any one of <1> to <9>, including forming the filter layers by an inkjet method.

The present invention makes it possible to solve the problems in related art and provide an organic electroluminescence device which does not cause image blurring, which has high light extraction efficiency (front luminance) and which makes it possible to reduce electricity consumption; and a method for producing the organic electroluminescence device.

### BRIEF DESCRIPTION OF THE DRAWINGS

FIG. 1A is a drawing showing an example of an organic electroluminescence device of the present invention (Part 1).

FIG. 1B is a schematic cross-sectional view of the organic electroluminescence device shown in FIG. 1A.

FIG. 1C is a drawing for explaining a green organic electroluminescence display portion in an organic electroluminescence device of the present invention, and a lens formed over the green organic electroluminescence display portion.

FIG. 2A is a schematic cross-sectional view showing an example of an organic electroluminescence device of the present invention.

FIG. 2B is a schematic cross-sectional view showing another example of an organic electroluminescence device of the present invention.

FIG. 3A is a drawing showing how light is waveguided in a conventional organic electroluminescence device (Part 1).

FIG. 3B is a drawing showing how light is waveguided in a conventional organic electroluminescence device (Part 2).

FIG. 3C is a drawing showing how light is waveguided in an organic electroluminescence device of the present invention (when colored lenses are used) (Part 1).

FIG. 3D is a drawing showing how light is waveguided in an organic electroluminescence device of the present invention (when colored lenses are used) (Part 2).

FIG. 3E is a drawing showing how light is waveguided in an organic electroluminescence device of the present invention (when color filters are used) (Part 1).

FIG. 3F is a drawing showing how light is waveguided in an organic electroluminescence device of the present invention (when color filters are used) (Part 2).

FIG. 4A is a drawing showing a method for producing an organic electroluminescence device of the present invention (when colored lenses are used) (Part 1).

FIG. 4B is a drawing showing a method for producing an organic electroluminescence device of the present invention (when colored lenses are used) (Part 2).

FIG. 4C is a drawing showing a method for producing an organic electroluminescence device of the present invention (when colored lenses are used) (Part 3).

FIG. 4D is a drawing showing a method for producing an organic electroluminescence device of the present invention (when colored lenses are used) (Part 4).

FIG. 4E is a drawing showing a method for producing an organic electroluminescence device of the present invention (when colored lenses are used) (Part 5).

FIG. 5A is a drawing showing a method for producing an organic electroluminescence device of the present invention (when color filters are used) (Part 1).

FIG. 5B is a drawing showing a method for producing an organic electroluminescence device of the present invention (when color filters are used) (Part 2).

FIG. 5C is a drawing showing a method for producing an organic electroluminescence device of the present invention (when color filters are used) (Part 3).

FIG. 5D is a drawing showing a method for producing an organic electroluminescence device of the present invention (when color filters are used) (Part 4).

FIG. 5E is a drawing showing a method for producing an organic electroluminescence device of the present invention (when color filters are used) (Part 5).

FIG. 5F is a drawing showing a method for producing an organic electroluminescence device of the present invention (when color filters are used) (Part 6).

FIG. 6A is a drawing showing passage of light in a colored lens.

FIG. 6B is a drawing showing passage of light in a lens, at whose interface on the side of a light-emitting layer a color filter is formed.

FIG. 6C is a drawing showing a color filter formed so as to cover the surface of a lens.

FIG. 6D is a diagram showing an example of a luminous intensity distribution in an organic electroluminescence display portion (sm=1).

FIG. 6E is a diagram showing an example of a luminous intensity distribution in an organic electroluminescence display portion (sm=2).

FIG. 7 is a drawing showing an example of an organic electroluminescence device of the present invention (Part 2).

FIG. 8 is a drawing showing an example of an organic electroluminescence device of the present invention (Part 3).

FIG. 9A is a diagram showing an example of a luminous intensity distribution in an organic electroluminescence display portion (Part 1).

FIG. 9B is a diagram showing an example of a luminous intensity distribution in an organic electroluminescence display portion (Part 2).

FIG. 10A is a drawing showing how organic electroluminescence display portions (lenses) are aligned in an organic electroluminescence device of Example 4.

FIG. 10B is a drawing showing how organic electroluminescence display portions (lenses) are aligned in an organic electroluminescence device of Example 5.

FIG. 11A is a drawing showing how organic electroluminescence display portions (lenses) are aligned in an organic electroluminescence device of Example 3.

FIG. 11B is a drawing showing how organic electroluminescence display portions (lenses) are aligned in an organic electroluminescence device of Example 6

FIG. 12A is a graph for explaining the light extraction efficiency in relation to the front luminance in each Example.

FIG. 12B is a drawing for explaining the outer diameter of a lens and the light-emitting width.

FIG. 13 is a graph for explaining the light extraction efficiency in relation to the integrated intensity in each Example.

### DETAILED DESCRIPTION OF THE INVENTION

### Organic Electroluminescence Device

An organic electroluminescence device of the present invention includes organic electroluminescence display portions, lenses and filter layers. If necessary, the organic electroluminescence device may further include oil-repellent layers, lipophilic layers and other members.

### <Organic Electroluminescence Display Portion>

Each organic electroluminescence display portion (organic electroluminescence element) includes at least an anode, a light-emitting layer and a cathode. If necessary, it may further include a hole injection layer, a hole transport layer, an electron injection layer, an electron transport layer, a sealing layer (barrier layer), a substrate, etc. Also, these layers may have other functions as well as their main functions. The material used to form each layer may be selected from a variety of materials.

The organic electroluminescence display portions are pixel elements (dots in pixel elements) which constitute pixels whose colors include red (R), green (G) and blue (B).

Regarding the structure of such pixels whose colors include red (R), green (G) and blue (B), a structure known in the art may be employed by using, for example, a tricolor light emission method in which pixel elements (dots in pixel elements) including light-emitting layers that emit lights corresponding to red, green and blue respectively as the above-mentioned light-emitting layers are formed and these pixel elements for red, green and blue respectively are disposed accordingly, as described on pp. 33-37 of the September 2000 issue of “Monthly Display”. —Anode—

The anode supplies holes to the hole injection layer, the hole transport layer, the light-emitting layer, etc. The material for the anode may be selected from metals, alloys, metal oxides, electroconductive compounds, and mixtures of these, and preference is given to materials which are 4 eV or more in work function. Specific examples of such materials include conductive metal oxides such as tin oxide, zinc oxide, indium oxide and indium tin oxide (ITO); metals such as gold, silver, chromium, nickel and aluminum; mixtures or laminated products of the metals and the conductive metal oxides; inorganic conductive materials such as copper iodide and copper sulfide; organic conductive materials such as polyaniline, polythiophenes and polypyrroles; and laminated products of these materials and ITO. Among these, conductive metal oxides are preferable, and ITO is particularly preferable in terms of productivity, conductivity, transparency and so forth.

The thickness of the anode is not particularly limited and may be suitably selected according to the material used for the anode; however, it is preferably in the range of 10 nm to 5 μm, more preferably 50 nm to 1 μm, even more preferably 100 nm to 500 nm.

The anode is generally a layer formed over a substrate such as a soda-lime glass substrate, alkali-free glass substrate or transparent resin substrate. In the case where glass is used, use of alkali-free glass is preferable in view of reduction in the amount of ions eluted from the glass. In the case where soda-lime glass is used, use of soda-lime glass barrier-coated with silica or the like is preferable.

The thickness of the substrate is not particularly limited as long as favorable mechanical strength can be maintained. In the case where glass is used as the substrate, its thickness is preferably 0.2 mm or greater, more preferably 0.7 mm or greater.

A barrier film may be used as the transparent resin substrate. The barrier film is a film including a plastic support and a gas-impermeable barrier layer provided on the plastic support. Examples of the barrier film include a barrier film produced by vapor deposition of silicon oxide or aluminum oxide (Japanese Patent Application Publication (JP-B) No. 53-12953 and JP-A No. 58-217344), a barrier film including an organic-inorganic hybrid coating layer (JP-A Nos. 2000-323273 and 2004-25732), a barrier film including an inorganic layer compound (JP-A No. 2001-205743), a barrier film in which inorganic material is layered (JP-A Nos. 2003-206361 and 2006-263989), a barrier film in which organic and inorganic layers are alternately stacked (JP-A No. 2007-30387, U.S. Pat. No. 6,413,645, and Thin Solid Films authored by Affinito et al., 1996, pp. 290-291), and a barrier film in which organic and inorganic layers are continuously stacked (U.S. Patent Application Publication No. 2004-46497).

The method for producing the anode may be selected from a variety of methods according to the material used for the anode. In the case of ITO, for example, a layer is formed by a method such as an electron beam method, sputtering, resistance heating vapor deposition, a chemical reaction method (e.g. a sol-gel method) or application of a dispersion of indium tin oxide. Also, by subjecting the anode to washing or other treatment, the drive voltage of a display device can be reduced, and luminous efficiency can be enhanced. In the case of ITO, for example, UV-ozone treatment or the like is effective.

### —Cathode—

The cathode supplies electrons to the electron injection layer, the electron transport layer, the light-emitting layer, etc. and is selected in view of its stability, ionization potential and adhesion to adjacent layer(s) such as the electron injection layer, the electron transport layer, the light-emitting layer, etc.

Examples of the material for the cathode include metals, alloys, metal oxides, electroconductive compounds, and mixtures of these. Specific examples of the material include alkali metals (such as Li, Na and K) and fluorides thereof, alkaline earth metals (such as Mg and Ca) and fluorides thereof, gold, silver, lead, aluminum, alloys or mixed metals of sodium and potassium, alloys or mixed metals of lithium and aluminum, alloys or mixed metals of magnesium and silver, indium, and rare earth metals (such as ytterbium). Among these, materials which are 4 eV or less in work function are preferable, particularly aluminum, alloys or mixed metals of lithium and aluminum, and alloys or mixed metals of magnesium and silver. The thickness of the cathode is not particularly limited and may be suitably selected according to the material used for the cathode; however, it is preferably in the range of 10 nm to 5 nm, more preferably 50 nm to 1 nm, even more preferably 100 nm to 1 nm.

The cathode is produced by a method such as an electron beam method, sputtering, resistance heating vapor deposition or a coating method. A single metal may be vapor-deposited, or two or more metals may be simultaneously vapor-deposited. Further, a plurality of metals may be simultaneously vapor-deposited so as to form an alloy electrode. Alternatively, a previously prepared alloy may be vapor-deposited.

The sheet resistances of the anode and the cathode are preferably low, or more specifically, preferably several hundred ohms per square or less each.

—Light-emitting layer—

The material for the light-emitting layer is not particularly limited and may be suitably selected according to the intended purpose. Examples of the material include materials which can form layers having functions such as a function of being injected with holes from the anode or the hole injection/transport layer and being injected with electrons from the cathode or the electron injection/transport layer when an electric field is applied, a function of transferring an injected charge, and a function of providing places for recombination of holes and electrons and thus effecting light emission.

Specific examples of the material for the light-emitting layer include benzoxazole derivatives, benzimidazole derivatives, benzothiazole derivatives, styrylbenzene derivatives, polyphenyl derivatives, diphenylbutadiene derivatives, tetraphenylbutadiene derivatives, naphthalimide derivatives, coumarin derivatives, perylene derivatives, perinone derivatives, oxadiazole derivatives, aldazine derivatives, pyrrolidine derivatives, cyclopentadiene derivatives, bisstyrylanthracene derivatives, quinacridone derivatives, pyrrolopyridine derivatives, thiadiazolopyridine derivatives, cyclopentadiene derivatives, styrylamine derivatives, aromatic dimethylidyne compounds, metal complexes typified by metal complexes of 8-quinolinol derivatives and rare earth complexes, and polymer compounds such as polythiophene, polyphenylene and polyphenylene vinylene. These may be used individually or in combination.

The thickness of the light-emitting layer is not particularly limited and may be suitably selected according to the intended purpose. It is preferably in the range of 1 nm to 5 μm, more preferably 5 nm to 1 μm, even more preferably 10 nm to 500 nm.

The method for forming the light-emitting layer is not particularly limited and may be suitably selected according to the intended purpose. Examples thereof include methods such as resistance heating vapor deposition, an electron beam method, sputtering, molecular lamination, coating methods (e.g. spin coating, casting, and dip coating) and the LB (Langmuir-Blodgett) method. Among these, resistance heating vapor deposition and coating methods are particularly preferable.

### —Hole Injection Layer and Hole Transport Layer—

The material(s) for the hole injection layer and the hole transport layer is/are not particularly limited as long as it/they has/have any of a function of being injected with holes from the anode, a function of transporting holes and a function of serving as a barrier against electrons injected from the cathode, and the material(s) may be suitably selected according to the intended purpose.

Examples of the material(s) for the hole injection layer and the hole transport layer include carbazole derivatives, triazole derivatives, oxazole derivatives, oxadiazole derivatives, imidazole derivatives, polyarylalkane derivatives, pyrazoline derivatives, pyrazolone derivatives, phenylenediamine derivatives, arylamine derivatives, amino-substituted chalcone derivatives, styrylanthracene derivatives, fluorenone derivatives, hydrazone derivatives, stylbene derivatives, silazane derivatives, aromatic tertiary amine compounds, styrylamine compounds, aromatic dimethylidene compounds, porphyrin compounds, polysilane compounds, poly(N-vinylcarbazole) derivatives, aniline copolymers, and conductive high molecular oligomers such as thiophene oligomers and polythiophene. These may be used individually or in combination.

The hole injection layer and the hole transport layer may have a single-layer structure including one material or two or more materials selected from the above-mentioned materials, or may have a multilayered structure including a plurality of layers of a single component or different components.

The hole injection layer and the hole transport layer may, for example, be formed by vacuum vapor deposition, the LB method, or a coating method (spin coating, casting, dip coating, etc.) in which a hole injection/transport agent is dissolved or dispersed in solvent and thusly applied. When a coating method is employed, the hole injection/transport agent may be dissolved or dispersed along with resin component(s).

The resin component(s) is/are not particularly limited and may be suitably selected according to the intended purpose. Examples thereof include polyvinyl chloride resins, polycarbonate resins, polystyrene resins, polymethyl methacrylate resins, polybutyl methacrylate resins, polyester resins, polysulfone resins, polyphenylene oxide resins, polybutadiene, poly(N-vinylcarbazole) resins, hydrocarbon resins, ketone resins, phenoxy resins, polyamide resins, ethyl cellulose, vinyl acetate resins, ABS resins, polyurethane resins, melamine resins, unsaturated polyester resins, alkyd resins, epoxy resins and silicone resins. These may be used individually or in combination.

The thickness of the hole injection layer and the thickness of the hole transport layer are not particularly limited and may be suitably selected according to the intended purpose but are preferably in the range of 1 nm to 5 μm each, more preferably 5 nm to 1 μm each, even more preferably 10 nm to 500 nm each.

### —Electron Injection Layer and Electron Transport Layer—

The material(s) for the electron injection layer and the electron transport layer is/are not particularly limited as long as it/they has/have any of a function of being injected with electrons from the cathode, a function of transporting electrons and a function of serving as a barrier against holes injected from the anode, and the material(s) may be suitably selected according to the intended purpose.

Examples of the material(s) for the electron injection layer and the electron transport layer include triazole derivatives, oxazole derivatives, oxadiazole derivatives, fluorenone derivatives, anthraquinodimethane derivatives, anthrone derivatives, diphenylquinone derivatives, thiopyran dioxide derivatives, carbodiimide derivatives, fluorenylidenemethane derivatives, distyrylpyrazine derivatives, heterocyclic tetracarboxylic acid anhydrides (such as naphthaleneperylene), phthalocyanine derivatives, and metal complexes typified by metal complexes of 8-quinolinol derivatives and metal complexes with ligands being metal phthalocyanine, benzoxazole, benzothiazole, etc. These may be used individually or in combination.

The electron injection layer and the electron transport layer may have a single-layer structure including one material or two or more materials selected from the above-mentioned materials, or may have a multilayered structure including a plurality of layers of a single component or different components.

The electron injection layer and the electron transport layer may, for example, be formed by vacuum vapor deposition, the LB method, or a coating method (spin coating, casting, dip coating, etc.) in which an electron injection/transport agent is dissolved or dispersed in solvent and thusly applied. When a coating method is employed, the electron injection/transport agent may be dissolved or dispersed along with resin component(s). The resin component(s) may, for example, be selected from the examples mentioned above in relation to the hole injection layer and the hole transport layer.

The thickness of the electron injection layer and the thickness of the electron transport layer are not particularly limited and may be suitably selected according to the intended purpose but are preferably in the range of 1 nm to 5 μm each, more preferably 5 nm to 1 μm each, even more preferably 10 nm to 500 nm each.

### —Sealing Layer (Barrier Layer)—

The sealing layer (barrier layer) is not particularly limited as long as it has a function of preventing permeation of oxygen, moisture, nitrogen oxides, sulfur oxides and ozone in the air, and the sealing layer may be suitably selected according to the intended purpose.

The material for the sealing layer (barrier layer) is not particularly limited and may be suitably selected according to the intended purpose. Examples thereof include SiN and SiON.

The thickness of the sealing layer (barrier layer) is not particularly limited and may be suitably selected according to the intended purpose; however, it is preferably in the range of 5 nm to 1,000 nm, more preferably 7 nm to 750 nm, particularly preferably 10 nm to 500 nm. When the thickness of the barrier layer is less than 5 nm, the sealing layer's barrier function with which to prevent permeation of oxygen and moisture in the air may be insufficient. When the thickness of the sealing layer is greater than 1,000 nm, there may be a decrease in light transmittance and degradation of transparency.

As for an optical property of the sealing layer (barrier layer), the sealing layer preferably has a light transmittance of 80% or greater, more preferably 85% or greater, even more preferably 90% or greater.

The method for forming the sealing layer (barrier layer) is not particularly limited and may be suitably selected according to the intended purpose. Examples thereof include CVD and vacuum vapor deposition.

### —Substrate—

Regarding the above-mentioned substrate, its shape, structure, size, etc. may be suitably selected. In general, the substrate is preferably shaped like a plate. The structure of the substrate may be a single-layer structure or a laminated structure. Also, the substrate may be formed of a single member or of two or more members. The substrate may be colorless and transparent or may be colored and transparent; however, it is preferred that the substrate be colorless and transparent because light emitted from the light-emitting layer is not scattered, attenuated, etc.

The material for the substrate is not particularly limited and may be suitably selected according to the intended purpose. Examples thereof include inorganic materials such as yttria-stabilized zirconia (YSZ) and glass; polyester resins such as polyethylene terephthalate resins, polybutylene phthalate resins and polyethylene naphthalate resins; and organic materials such as polystyrene resins, polycarbonate resins, polyethersulfone resins, polyarylate resins, polyimide resins, polycycloolefin resins, norbornene resins and poly(chlorotrifluoroethylene) resins. These may be used individually or in combination.

In the case where glass is used as the substrate, use of alkali-free glass is preferable in view of reduction in the amount of ions eluted from the glass. In the case where soda-lime glass is used, use of soda-lime glass barrier-coated with silica or the like (e.g. a barrier film substrate) is preferable. In the case where an organic material is used as the substrate, the organic material is preferably favorable in heat resistance, dimensional stability, solvent resistance, electrical insulation and processability.

In the case where a thermoplastic substrate is used as the substrate, a hard coat layer, an undercoat layer, etc. may be additionally provided if necessary.

Here, the structure of each organic electroluminescence display portion is not particularly limited and may be suitably selected according to the intended purpose. For example, selection may be made regarding (1) the reflectance of en electrode on the light emission side in the organic electroluminescence display portion, (2) the optical length of a microcavity structure, and (3) the use of a bottom emission type or a top emission type.

As the electrode on the light emission side in the organic electroluminescence display portion, mentioned in (1) above, in the case of a bottom emission type, it is possible to use a transparent electrode (for example an ITO electrode) which has a reflectance of 10% or less as measured from the side of the light-emitting layer, or a semipermeable electrode (for example an Ag electrode) which has a reflectance of more than 10% as measured from the side of the light-emitting layer. When a transparent electrode is used as the electrode on the light emission side, a microcavity structure may not be able to be formed because of the weak reflection of light. When a semipermeable electrode is used as the electrode on the light emission side, a microcavity structure can be formed.

In the case of a top emission type, a semipermeable electrode which has a reflectance of more than 10% as measured from the side of the light-emitting layer is used as the electrode on the light emission side so as to form a microcavity structure.

The optical length of a microcavity structure, mentioned in (2) above, can be suitably adjusted by changing the thickness of organic compound layer(s) placed between the anode and the cathode, which are components of the organic electroluminescence display portion. The organic compound layer(s) is/are not particularly limited and may be suitably selected according to the intended purpose. Examples thereof include a hole transport layer, a hole injection layer, a light-emitting layer, an electron transport layer and an electron injection layer. Here, the microcavity structure means a structure in which a semipermeable reflective layer on the light emission side and a reflective layer on the side opposite to the light emission side interfere with each other.

Here, the optical length (optical distance) L of the microcavity structure is represented by the equation L=2×Σnᵢdᵢ (i denotes a mixed number composed of integers of 1 to i) and a reflection phase shift, or more specifically, the sum of products of the thickness d of each layer (formed between an anode and a cathode) and the refractive index n of the layer.

The relationship between the optical length L and the emission wavelength is as follows: L(λ)=mλ, (when m=1, it means that a primary microcavity structure is employed; when m=2, it means that a secondary microcavity structure is employed; when m=3, it means that a tertiary microcavity structure is employed). The optical length L(λ) is represented by the following equation.

$$L ( λ ) \approx 2 {\sum }_{j} {n}_{j} {L}_{j} + {\sum }_{i} \vert \begin{matrix}{ϕ}_{mi} \\ 2 π \end{matrix} λ \vert \text{:} Optical length of microcavity$$

$${ϕ}_{m} = arc tan ( \frac{2 {n}_{s} {k}_{m}}{{n}_{s}^{2} - {n}_{m}^{2} - {k}_{m}^{2}} )$$

ns: Refractive index of organic layer in contact with metal reflective layer
nm+km: Complex refractive index of metal reflective layer

In the above equation, L(λ) denotes an optical length [=2Σnⱼdⱼ+ΣABS(φₘᵢλ/2π)], λ denotes an emission wavelength, i denotes a suffix showing a metal reflective layer, and j denotes a suffix showing a layer (an organic layer, a dielectric layer, etc.) between metal layers, other than a metal reflective layer.

When the microcavity structure is a primary microcavity structure, it means that the optical length L(λ) is 1λ (λ denotes an emission wavelength), and the optical length is the shortest optical length which allows intensification of light traveling in a round-trip manner between metal reflective layers.

When the microcavity structure is a secondary microcavity structure, it means that the optical length L(λ) is 2λ (λ denotes an emission wavelength), and the optical length is the second shortest, in comparison with the shortest optical length which allows intensification of light traveling in a round-trip manner between metal reflective layers.

When the microcavity structure is a tertiary microcavity structure, it means that the optical length L(λ) is 3λ (λ denotes an emission wavelength), and the optical length is the third shortest, in comparison with the shortest optical length which allows intensification of light traveling in a round-trip manner between metal reflective layers.

### <Lens>

Each of the lenses is placed over each organic electroluminescence display portion and has a function of controlling an optical path of light emitted from the light-emitting layer. Here, the expression “placed over each organic electroluminescence display portion” refers to not only a case where the lens is directly placed on a light extraction surface of the organic electroluminescence display portion, but also a case where the lens is placed above the light extraction surface of the organic electroluminescence display portion.

As the light extraction surface, a glass substrate may, for example, be used in the case of a bottom emission type, and a sealing layer (barrier layer) may, for example, be used in the case of a top emission type.

The shape, size, material, etc. of the lenses are not particularly limited and may be suitably selected according to the intended purpose.

The shape of the lenses is not particularly limited and may be suitably selected according to the intended purpose. For example, each lens may be shaped like a sphere, a hemisphere, an ellipse, a trapezoid or the like. It is preferred that each lens be shaped like a hemisphere in terms of increase in front luminance.

The material for the lenses is not particularly limited and may be suitably selected according to the intended purpose. Examples of the material include UV inks (ultraviolet curable inks), transparent resins, glasses, transparent crystals and transparent ceramics. Among these, UV inks (ultraviolet curable inks) are preferable in that they can be processed at low temperatures and thus damage done to organic EL layers is small.

The refractive index of the lenses is not particularly limited and may be suitably selected according to the intended purpose. Nevertheless, it is preferably in the range of 1.4 to 1.9. When the refractive index is less than 1.4, there may be a decrease in light extraction efficiency. When the refractive index is greater than 1.9, there may be an increase in luminance variation relative to the angle.

The UV inks (ultraviolet curable inks) are not particularly limited and may be suitably selected according to the intended purpose. Preferred examples thereof include a UV ink prepared by adding a photoinitiator, a thermosetting material, a dispersant, etc. to PMMA.

The size of the lenses is not particularly limited and may be suitably selected according to the intended purpose. Nevertheless, the effective diameter of each lens is preferably in the range of 10 μm to 1,000 μm, more preferably 20 μm to 200 μm, in the case of hemispherical lenses.

The arrangement of the lenses is not particularly limited and may be suitably selected according to the intended purpose. For example, the lenses may be disposed in the form of a square lattice, a honeycomb, etc.

The method for producing the lenses is not particularly limited and may be suitably selected according to the intended purpose. Examples thereof include inkjet methods, imprinting methods and photolithography methods. Among these, inkjet methods are preferable in that a plurality of kinds of inks can be separately applied with ease in the case where colored lenses are produced.

In the inkjet methods, for example, an oil-repellent layer (described below) may be formed on each organic electroluminescence display portion, a lipophilic layer (described below) may be formed on the oil-repellent layer, and a lens may be selectively formed over the lipophilic layer.

In the imprinting methods, for example, a lens may be formed over each organic electroluminescence display portion by applying a composition that contains a release agent and a UV curable resin onto a transparent mold, then pressing the transparent mold onto the organic electroluminescence display portion, which is accompanied by UV light irradiation, and then separating the transparent mold.

In the case where a light-extracting component such as a lens is not attached to the organic electroluminescence display portion, light with any angle greater than a total reflection angle of ±33° at the interface between the glass and the air is not emitted into the air.

### <Filter Layer>

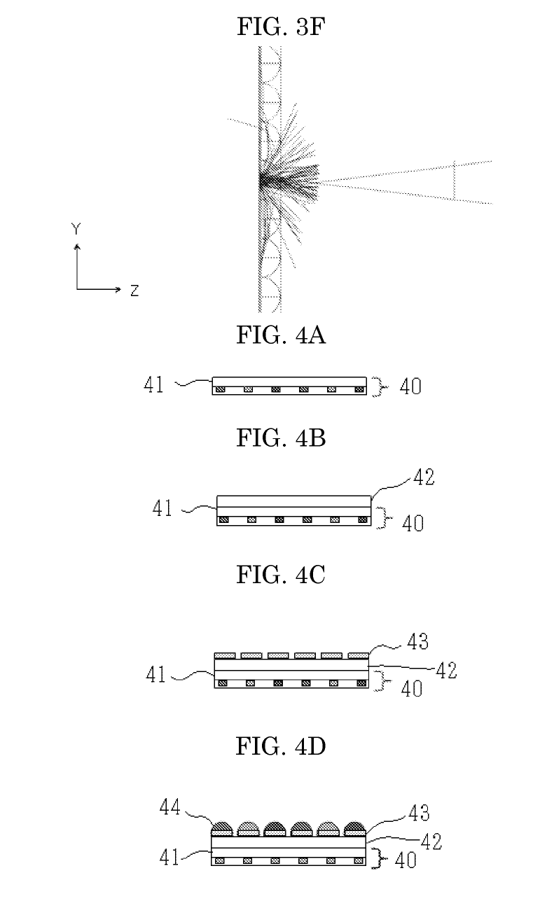

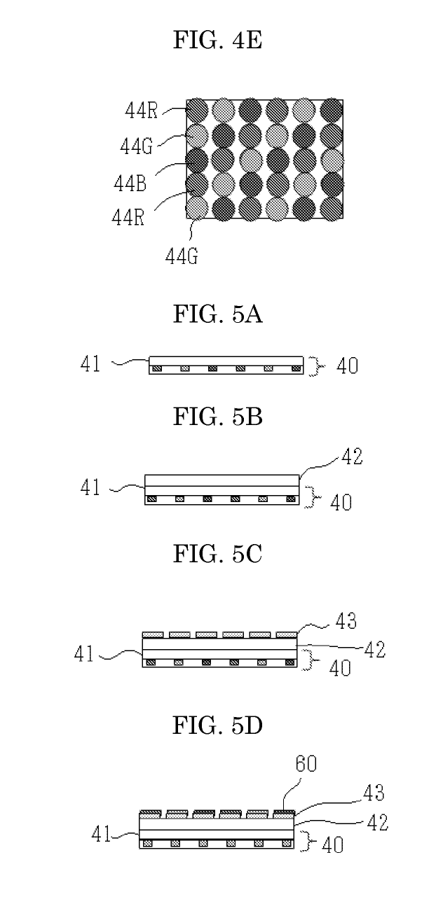

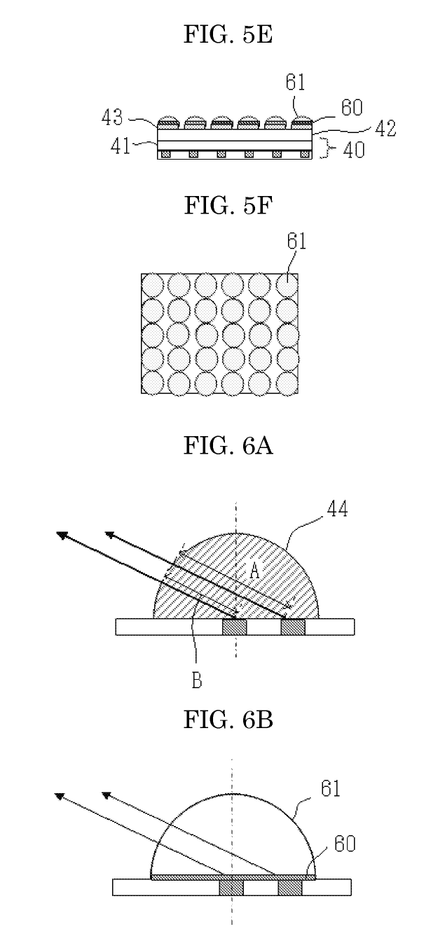

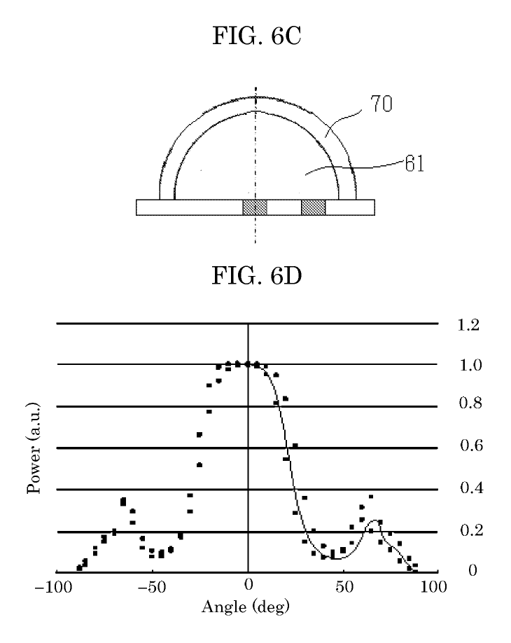

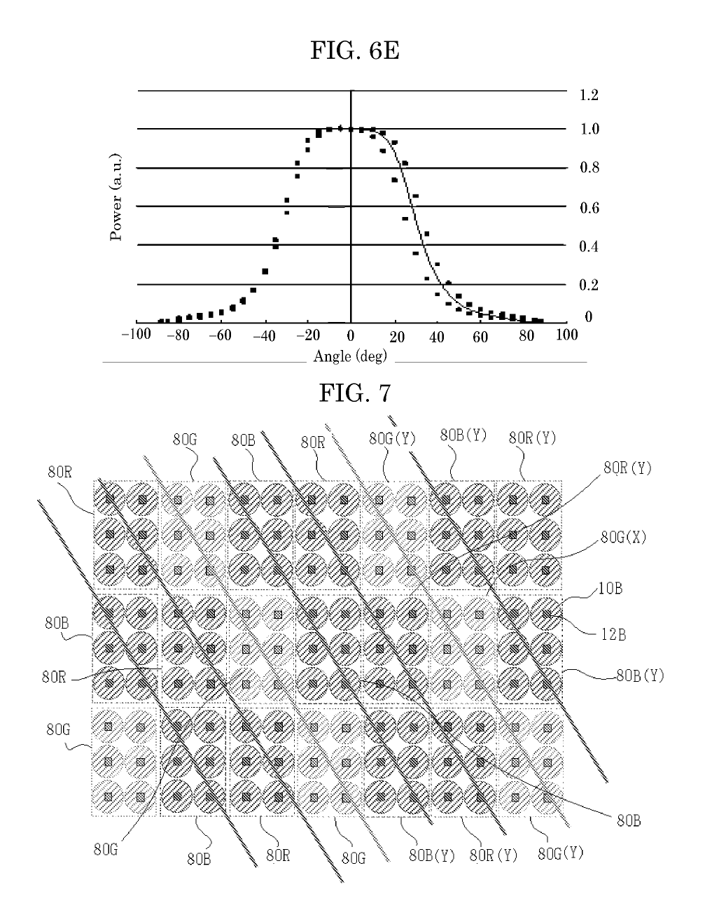

The filter layers are not particularly limited as long as each filter layer is formed integrally with each lens (which is placed over each organic electroluminescence display portion) and placed so as to cover an optical path in each lens, and transmits the light emitted from the light-emitting layer in each organic electroluminescence display portion. And the filter layers may be suitably selected according to the intended purpose. For example, there are an aspect in which a lens functions as a filter layer (a lens 44 in FIGS. 4D and 6A), an aspect in which a filter layer is formed at the interface of a lens on the side of a light-emitting layer (a filter layer 60 in FIGS. 5D and 6B), and an aspect in which a filter layer is formed so as to cover the surface of a lens (a filter layer 70 in FIG. 6C).

Each filter layer is formed of a material whose color is the same as the color of the light emitted from the light-emitting layer in each organic electroluminescence display portion, and it transmits the light emitted from the light-emitting layer.

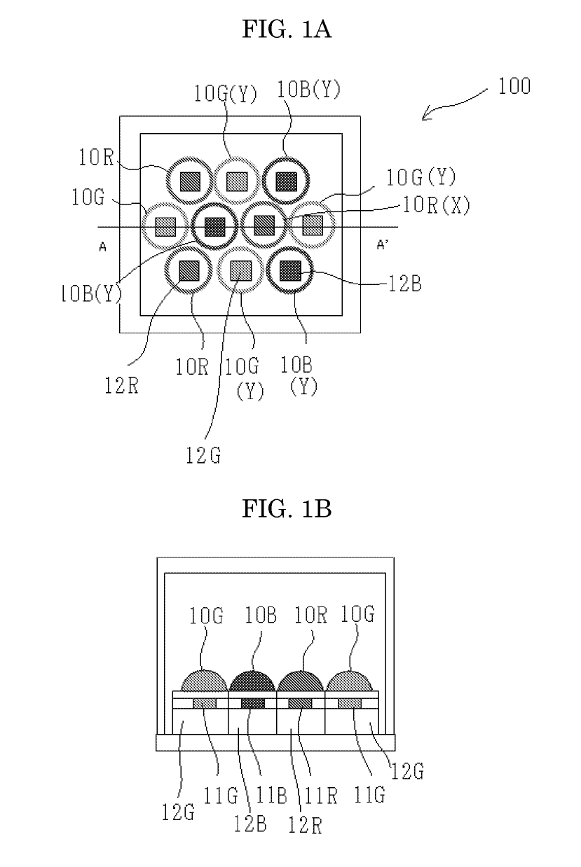

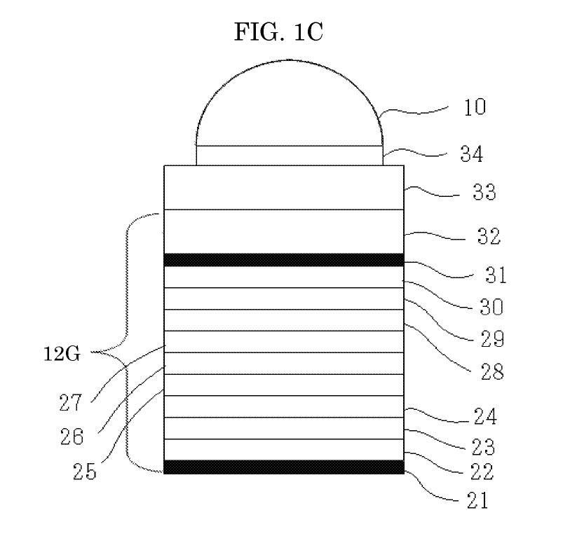

For example, as shown in FIGS. 1A and 1B, a red lens (filter layer) 10R which transmits red light is placed over an organic electroluminescence display portion 12R including a light-emitting layer 11R which emits red light, a green lens (filter layer) 10G which transmits green light is placed over an organic electroluminescence display portion 12G including a light-emitting layer 11G which emits green light, and a blue lens (filter layer) 10B which transmits blue light is placed over an organic electroluminescence display portion 12B including a light-emitting layer 11B which emits blue light.

The lens (filter layer) 10R is formed of a red material whose color is the same as the red light emitted from the light-emitting layer 11R, and transmits the red light emitted from the light-emitting layer 11R. The lens (filter layer) 10G is formed of a green material whose color is the same as the green light emitted from the light-emitting layer 11G, and transmits the green light emitted from the light-emitting layer 11G. The lens (filter layer) 10B is formed of a blue material whose color is the same as the blue light emitted from the light-emitting layer 11B, and transmits the blue light emitted from the light-emitting layer 11B.

The thickness of the filter layers is not particularly limited and may be suitably selected according to the intended purpose. Nevertheless, the thickness of each filter layer is preferably in the range of 0.1 μm to 5 μm, more preferably 0.5 μm to 5 μm, particularly preferably 2 μm to 3 μm, in the aspect in which the filter layer is formed at the interface of the lens on the side of the light-emitting layer or the aspect in which the filter layer is formed so as to cover the surface of the lens.

When the thickness is less than 0.5 μm, a desired concentration may not be obtained. When the thickness is greater than 5 μm, it is difficult to control the thickness, there may be an increase in surface roughness, and thus light scattering may be induced. Conversely, when the thickness is in the particularly preferred range, there is an advantage in terms of production suitability and yield.

The material for the filter layers is not particularly limited and may be suitably selected according to the intended purpose. Examples of the material include UV inks (ultraviolet curable inks), transparent resins, glasses, transparent crystals and transparent ceramics, which may be mixed with pigments and dyes. Among these, UV inks (ultraviolet curable inks) are preferable in that they can be processed at low temperatures and thus damage done to organic EL layers is small.

The UV inks (ultraviolet curable inks) are not particularly limited and may be suitably selected according to the intended purpose. Preferred examples thereof include a UV ink prepared by adding a photoinitiator, a thermosetting material, a dispersant, etc. to PMMA.

The pigments are not particularly limited and may be suitably selected according to the intended purpose.

The dyes are not particularly limited and may be suitably selected according to the intended purpose.

The method for producing the filter layers is not particularly limited and may be suitably selected according to the intended purpose. Examples thereof include inkjet methods, imprinting methods and photolithography methods. Among these, inkjet methods are preferable in that separate application of inks is possible in one process and an apparatus for producing the lenses can be utilized to produce the filter layers.

In the inkjet methods, for example, an oil-repellent layer (described below) may be formed on each organic electroluminescence display portion, a lipophilic layer (described below) may be formed on the oil-repellent layer, and a filter layer may be selectively formed over the lipophilic layer.

In the imprinting methods, for example, a filter layer may be formed over each organic electroluminescence display portion by applying a composition that contains a release agent and a UV curable resin onto a transparent mold, then pressing the transparent mold onto the organic electroluminescence display portion, which is accompanied by UV light irradiation, and then separating the transparent mold.

### <Oil-Repellent Layer>

The oil-repellent layer is not particularly limited as long as it repels an ink such as UV ink (ultraviolet curable ink), and it may be suitably selected according to the intended purpose. For example, the oil-repellent layer may be an organic fluoride film. Suitable examples of the material for the oil-repellent layer include CYTOP (manufactured by ASAHI GLASS CO., LTD.) and FLUORINERT (manufactured by 3M Company).

The oil-repellent layer repels an ink such as UV ink (ultraviolet curable ink). Accordingly, provision of a lipophilic layer (mentioned below) on the oil-repellent layer makes it possible to form an ink layer selectively over the lipophilic layer. Additionally, the oil-repellent layer may function also as a low-refractive-index layer.

The thickness of the oil-repellent layer is not particularly limited and may be suitably selected according to the intended purpose. Nevertheless, it is preferably in the range of 0.5 μm to 10 μm, more preferably 1 μm to 5 μm, particularly preferably 2 μm to 3 μm.

When the thickness of the oil-repellent layer is less than 0.5 μm, it may act as an interference film and thus thickness unevenness may induce luminance unevenness. When the thickness is greater than 10 μm, the NA of a lens decreases, which may cause a dramatic drop in luminance on the high angle side. Conversely, when the thickness is in the particularly preferred range, there is an advantage in that there is an appropriate drop in luminance and the extent of luminance unevenness is small.

The method for forming the oil-repellent layer is not particularly limited and may be suitably selected according to the intended purpose. For example, it may be formed using SiO₂, SiON, Si₃N₄, etc. Among these, SiO₂ is preferable in that it yields a stable refractive index and enables the oil-repellent layer to be produced with ease.

### <Lipophilic Layer>

The lipophilic layer is not particularly limited as long as it has a high affinity for an ink such as UV ink (ultraviolet curable ink), and it may be suitably selected according to the intended purpose. For example, it may be an SiO₂ film. The lipophilic layer has a high affinity for an ink such as UV ink (ultraviolet curable ink), and thus an ink layer can be selectively formed over the lipophilic layer.

The thickness of the lipophilic layer is not particularly limited and may be suitably selected according to the intended purpose. Nevertheless, it is preferably in the range of 20 nm to 5,000 nm, more preferably 50 nm to 1,000 nm, particularly preferably 100 nm to 500 nm.

When the thickness is less than 20 nm, a pinhole-related defect may arise. When the thickness is greater than 5,000 nm, the lipophilic layer may detach owing to film stress. Conversely, when the thickness is in the particularly preferred range, there is an advantage in terms of film adhesion and yield.

The method for forming the lipophilic layer is not particularly limited and may be suitably selected according to the intended purpose. Examples of the method include sputtering, CVD and vacuum vapor deposition. Among these, sputtering is preferable in that favorable adhesion can be secured and low-temperature deposition is enabled.

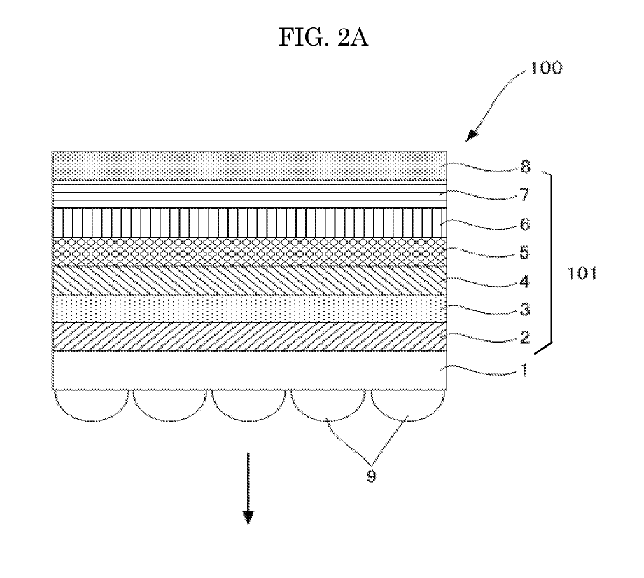

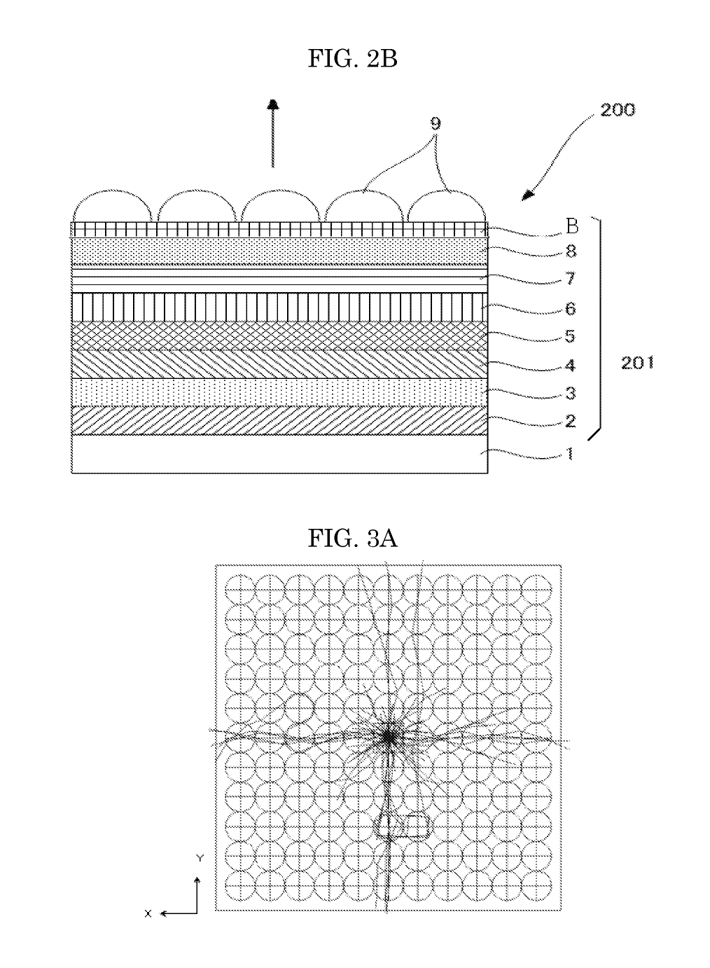

FIG. 2A is a schematic cross-sectional view showing a bottom emission type organic electroluminescence device as an example of an organic electroluminescence device of the present invention. FIG. 2B is a schematic cross-sectional view showing a top emission type organic electroluminescence device as an example of an organic electroluminescence device of the present invention.

A bottom emission type organic electroluminescence device 100 in FIG. 2A includes a glass substrate 1, an organic electroluminescence display portion 101 (an anode 2, a hole injection layer 3, a hole transport layer 4, a light-emitting layer 5, an electron transport layer 6, an electron injection layer 7 and a cathode 8) placed on the glass substrate 1, and lenses 9 formed on the light extraction surface side of the glass substrate 1, with an oil-repellent layer (not shown) and a lipophilic layer (not shown) being present between the lenses 9 and the glass substrate 1.

A top emission type organic electroluminescence device 200 in FIG. 2B includes a glass substrate 1, an organic electroluminescence display portion 201 (an anode 2, a hole injection layer 3, a hole transport layer 4, a light-emitting layer 5, an electron transport layer 6, an electron injection layer 7 and a cathode 8) placed on the glass substrate 1, a gas barrier layer B formed on the cathode 8, and lenses 9 formed on the light extraction surface side of the gas barrier layer B, with an oil-repellent layer (not shown) and a lipophilic layer (not shown) being present between the lenses 9 and the gas barrier layer B.

The term “light emission direction” means the direction in which light coming from the light-emitting layer is emitted from the light extraction surface toward the outside of the organic electroluminescence device. In the case of the bottom emission type organic electroluminescence device 100 shown in FIG. 2A, the light emission direction means the downward direction (as indicated by the arrow) which is parallel to the drawing, as seen from the light-emitting layer 5. In the case of the top emission type organic electroluminescence device 200 shown in FIG. 2B, the light emission direction means the upward direction (as indicated by the arrow) which is parallel to the drawing, as seen from the light-emitting layer 5.

The organic electroluminescence device of the present invention may be constructed as a device capable of full-color display.

Examples of methods of constructing the organic electroluminescence device of the present invention as a full-color type include a tricolor light emission method in which layers that emit lights corresponding to three primary colors (blue (B), green (G) and red (R)) respectively are disposed over a substrate (as described on pp. 33-37 of the September 2000 issue of “Monthly Display”); a white color method in which white light emitted by means of a layer structure for white light emission is passed through a color filter and thus divided into three primary colors; and a color conversion method in which blue light emitted by means of a layer structure for blue light emission is passed through a fluorescent pigment layer and thus converted to red (R) light and green (G) light.

Also, by combining a plurality of layer structures for different light emission colors, obtained by any of the above-mentioned methods, it is possible to obtain a flat-type light source of a desired light emission color. Examples of such a light source include a white emission light source that is a combination of blue and yellow organic electroluminescence display portions (light-emitting elements), and a white emission light source that is a combination of blue, green and red organic electroluminescence display portions (light-emitting elements).

### <Placement of Organic Electroluminescence Display Portion, Lens and Filter Layer>

The organic electroluminescence device includes a plurality of organic electroluminescence display portions and a plurality of lenses, wherein a filter layer formed integrally with one lens among the lenses absorbs at least light with a peak wavelength among light which has passed through at least one of lenses that are adjacent to the one lens.

For example, as shown in FIGS. 1A and 1B, an organic electroluminescence device 100 includes a plurality of organic electroluminescence display portions, i.e. 12R, 12B and 12G, and a plurality of lenses, i.e. 10R, 10B and 10G. Among the lenses 10, one lens (filter layer) 10R(X) absorbs at least green and blue lights with peak wavelengths among green and blue lights which have respectively passed through lenses 10G(Y) and 10B(Y) that are adjacent to the one lens 10R(X).

Light with a peak wavelength among light which has passed through a lens means light with a wavelength that is highest in light intensity among light which has passed through a lens. For instance, red light has a peak wavelength of 630 nm, green light has a peak wavelength of 530 nm, and blue light has a peak wavelength of 470 nm.

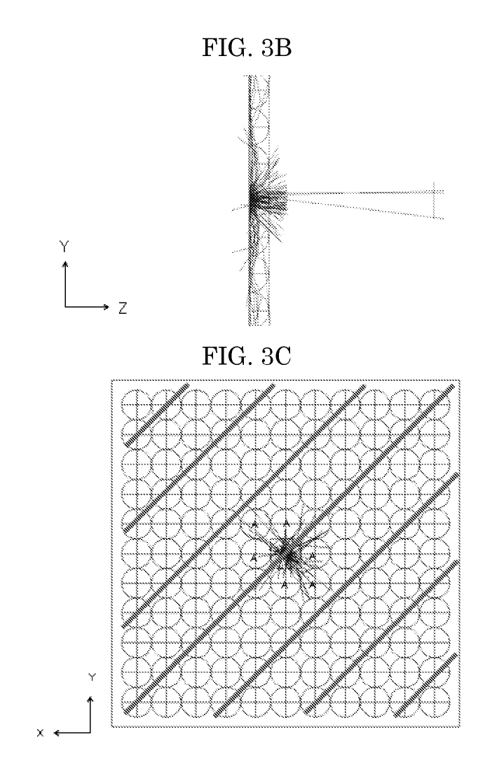

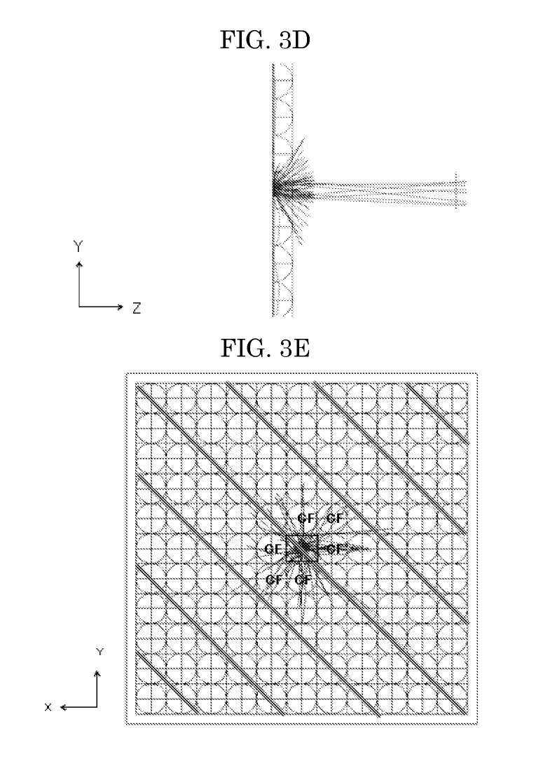

In FIGS. 1A and 1B, for example, the one lens (filter layer) 10R(X) absorbs at least green and blue lights with peak wavelengths among green and blue lights which have respectively passed through all of the lenses 10G(Y) and 10B(Y) that are adjacent to the one lens 10R(X). Specifically, the color (red) of the one lens (filter layer) 10R(X) is different from the colors (green and blue) of all of the lenses 10G(Y) and 10B(Y) that are adjacent to the one lens 10R(X); here, it should be noted that one lens (filter layer) is satisfactory provided that it absorbs at least light with a peak wavelength among light which has passed through at least one of lenses that are adjacent to the one lens. Examples of aspects include an aspect in which one lens (filter layer) absorbs at least lights with peak wavelengths among lights which have passed through lenses aligned in at least two directions among lenses that are adjacent to the one lens, and an aspect in which one lens (filter layer) absorbs at least lights with peak wavelengths among lights which have passed through lenses aligned in at least three directions among lenses that are adjacent to the one lens. Parenthetically, FIGS. 3C and 3E, which will be later explained, show aspects in which one lens (filter layer) absorbs at least lights with peak wavelengths among lights which have passed through lenses aligned in three directions among lenses that are adjacent to the one lens.

In the organic electroluminescence device, the distance between each organic electroluminescence display portion and each lens is not particularly limited and may be suitably selected according to the intended purpose. Nevertheless, it is preferably 20 μm or less.

FIG. 1C is a drawing for explaining a green organic electroluminescence display portion in an organic electroluminescence device of the present invention, and a lens formed over the green organic electroluminescence display portion.

A green organic electroluminescence display portion 12G includes a substrate (not shown), an anode 21 (for example an Al layer having a thickness of 100 nm) formed on the substrate, a hole injection layer 22 (for example a 2-TNATA/MnO₃ layer having a thickness of 20 nm) formed on the anode 21, a first hole transport layer 23 (for example a 2-TNATA/F4-TCNQ layer having a thickness of 141 nm) formed on the hole injection layer 22, a second hole transport layer 24 (for example an α-NPD layer having a thickness of 10 nm) formed on the first hole transport layer 23, a third hole transport layer 25 (for example a layer which is formed of the hole transport material A shown below and has a thickness of 3 nm) formed on the second hole transport layer 24, a light-emitting layer 26 (for example a layer which is formed of CBP and the light-emitting material A shown below and has a thickness of 20 nm) formed on the third hole transport layer 25, a first electron transport layer 27 (for example a BAlq layer having a thickness of 39 nm) formed on the light-emitting layer 26, a second electron transport layer 28 (for example a BCP layer having a thickness of 1 nm) formed on the first electron transport layer 27, a first electron injection layer 29 (for example an LiF layer having a thickness of 1 nm) formed on the second electron transport layer 28, a second electron injection layer 30 (for example an Al layer having a thickness of 1 nm) formed on the first electron injection layer 29, a cathode 31 (for example an Ag layer having a thickness of 20 nm) formed on the second electron injection layer 30, and a sealing layer 32 (for example an SiON layer having a thickness of 3,000 nm) formed on the cathode 31.

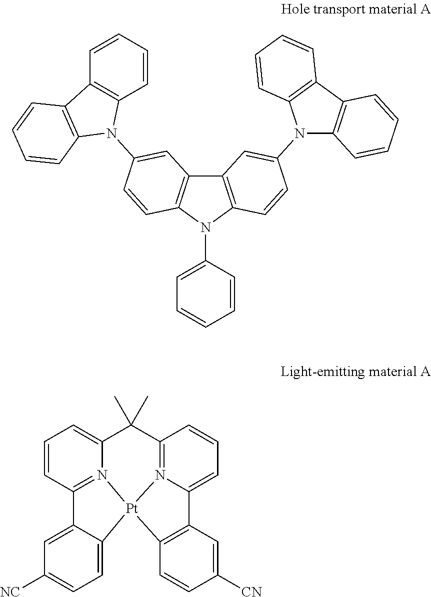

An oil-repellent layer 33 (for example an organic fluoride resin layer having a thickness of 3,000 nm) is formed on the green organic electroluminescence display portion 12G, and a lipophilic layer 34 (for example an SiO₂ layer having a thickness of 100 nm) is formed on the oil-repellent layer 33, and a green lens 10G (for example an acrylic resin lens) is formed on the lipophilic layer 34.

FIG. 3A is a drawing showing how light is waveguided in a conventional organic electroluminescence device (Part 1), FIG. 3B is a drawing showing how light is waveguided in a conventional organic electroluminescence device (Part 2), FIG. 3C is a drawing showing how light is waveguided in an organic electroluminescence device of the present invention (when colored lenses are used) (Part 1), FIG. 3D is a drawing showing how light is waveguided in an organic electroluminescence device of the present invention (when colored lenses are used) (Part 2), FIG. 3E is a drawing showing how light is waveguided in an organic electroluminescence device of the present invention (when color filters are used) (Part 1), and FIG. 3F is a drawing showing how light is waveguided in an organic electroluminescence device of the present invention (when color filters are used) (Part 2).

In the case where transparent lenses are attached onto 11×11 organic electroluminescence display portions (light-emitting pixel elements) arranged in the form of a square lattice as shown in FIG. 3A, light enters from one lens (the lens at the center in FIG. 3A (the enclosed lens)) into lenses adjacent to the one lens and propagates especially in vertical and horizontal directions, as shown in FIGS. 3A and 3B. Emission of the propagating light from lenses causes image bleeding. Accordingly, the lenses (organic electroluminescence display portions) are arranged such that the color of the one lens (the lens at the center in FIG. 3C (the enclosed lens)) differs from the colors of lenses adjacent to the one lens with respect to the vertical and horizontal directions, as shown in FIG. 3C. Note that in FIG. 3C, each lens A is formed of a medium (whose color is different from the color of the lens at the center (the enclosed lens)) which absorbs at least light with a peak wavelength among light emitted from the lens at the center (the enclosed lens). This makes it possible to greatly reduce the amount of light propagated to the adjacent lenses, as shown in FIG. 3D.

As shown in FIG. 3E, color filters (organic electroluminescence display portions) are arranged such that the color of a color filter placed under one lens (the lens at the center in FIG. 3E (the enclosed lens)) differs from the colors of color filters placed under lenses that are adjacent to the one lens with respect to vertical and horizontal directions. Note that in FIG. 3E, each color filter CF is formed of a medium (whose color is different from the color of the color filter placed under the lens at the center (the enclosed lens)) which absorbs at least light with a peak wavelength among light emitted from the lens at the center (the enclosed lens). This proves that light which propagates for a long distance is absorbed by the color filters CF, as shown in FIG. 3F.

Here, a method for producing an organic electroluminescence device, in which lenses function as filter layers, is explained, referring to FIGS. 4A to 4E.

First of all, an organic electroluminescence display portion 40 including an SiON layer 41 (as a sealing layer) formed at the upper surface is produced by a method known in the art (FIG. 4A).

Next, an organic fluoride (CYTOP, manufactured by ASAHI GLASS CO., LTD.) is deposited thereon by spin coating so as to form an organic fluoride film 42 (as an oil-repellent layer) having a thickness of 3,000 nm. Thereafter, the organic electroluminescence display portion 40 with the organic fluoride film 42 is post-baked at 150° C. or lower, preferably 100° C. or lower (FIG. 4B).

Next, a mask (not shown) is neatly placed over the organic fluoride film 42, then an SiO₂ film 43 (as a lipophilic layer) having a thickness of 100 nm is produced by RF sputtering (FIG. 4C).

Subsequently, UV cleaning is carried out, then patterning with a UV ink is performed on the SiO₂ film 43 by an inkjet method (FIG. 4D). After that, UV light is applied to cure the UV ink, and lenses 44 are thus formed. In this inkjet method, an ink mixed with a pigment or dye is used.

Here, a method for producing an organic electroluminescence device, in which filter layers are formed at interfaces of lenses on the side of light-emitting layers, is explained referring to FIGS. 5A to 5F.

First of all, an organic electroluminescence display portion 40 including an SiON layer 41 (as a sealing layer) formed at the upper surface is produced by a method known in the art (FIG. 5A).

Next, an organic fluoride (CYTOP, manufactured by ASAHI GLASS CO., LTD.) is deposited thereon by spin coating so as to form an organic fluoride film 42 (as an oil-repellent layer) having a thickness of 3,000 nm. Thereafter, the organic electroluminescence display portion 40 with the organic fluoride film 42 is post-baked at 150° C. or lower, preferably 100° C. or lower (FIG. 5B).

Next, a mask (not shown) is neatly placed over the organic fluoride film 42, then an SiO₂ film 43 (as a lipophilic layer) having a thickness of 100 nm is produced by RF sputtering (FIG. 5C).

Subsequently, UV cleaning is carried out, then patterning with a UV ink is performed on the SiO₂ film 43 by an inkjet method (FIG. 5D). After that, UV light is applied to cure the UV ink, and filters 60 having a thickness of 1 μm each are thus formed. In this inkjet method, an ink mixed with a pigment or dye is used.

Thereafter, patterning with a transparent UV ink is performed by an inkjet method. Then UV light is applied to cure the UV ink, and lenses 61 are thus formed (FIGS. 5E and 5F).

Note that when a colored lens 44 is used as shown in FIG. 6A, there are optical path lengths A and B of light passing through the lens 44, which differ from each other depending upon the position where the light passes. This affects color tones of a light-emitting device. Meanwhile, in a structure where a color filter 60 is provided immediately under a lens 61 as shown in FIG. 6B, the optical path length of light passing through the color filter 60 does not much vary depending upon the position where it passes.

In comparison with an organic electroluminescence element which has a primary microcavity structure in terms of an optical length (sm=1) (FIG. 6E), an organic electroluminescence element which has a secondary microcavity structure in terms of an optical length (sm=2) (FIG. 6D) has a noticeable effect of reducing the amount of light propagated to adjacent organic electroluminescence display portions (lenses). This is due to an abundance of light components on the high angle side.

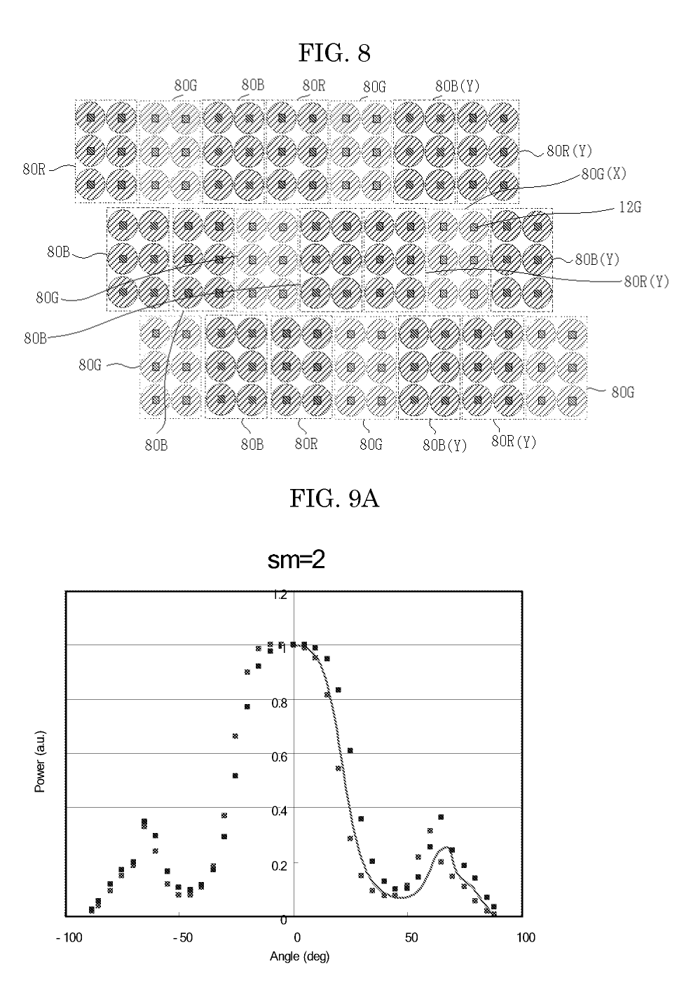

As shown in FIGS. 7 and 8, a plurality of organic electroluminescence display portions 12 (lenses 10) may be provided as dots in one pixel element 80.

In FIG. 7, there is a plurality of pixel elements 80 each having a plurality of organic electroluminescence display portions 12 including light-emitting layers which emit light of the same color, wherein the light-emitting layers of the green organic electroluminescence display portions 12G in one green pixel element 80G(X) in the pixel elements 80 emit light whose color is different from the color(s) of light(s) emitted by the light-emitting layers of the blue organic electroluminescence display portions 12B and/or the light-emitting layers of the red organic electroluminescence display portions 12R in at least one pixel element (blue pixel element 80B(Y) and/or red pixel element 80R(Y)) among pixel elements (green pixel element 80G(Y), blue pixel element 80B(Y) and red pixel element 80R(Y)) that are adjacent to the one green pixel element 80G(X).

In FIG. 8, light-emitting layers of green organic electroluminescence display portions 12G in one green pixel element 80G(X) among a plurality of pixel elements 80 emit light whose color is different from the colors of lights emitted by light-emitting layers of blue organic electroluminescence display portions 12B and light-emitting layers of red organic electroluminescence display portions 12R in pixel elements (blue pixel element 80B(Y), red pixel element 80R(Y)) that are adjacent to the one green pixel element 80G(X).

Note that when the pixels are not disposed in the form of a square lattice but disposed diagonally as shown in FIG. 8, a greater effect of reducing the amount of light propagated to adjacent organic electroluminescence display portions (lenses) can be obtained. This is because pixels of the same color are disposed along diagonal lines, so that propagation of light in the direction of the diagonal lines is allowed.

In FIGS. 7 and 8, one pixel includes a green pixel element 80G, a blue pixel element 80B and a red pixel element 80R. The pixel elements 80G, 80B and 80R respectively include, as plurality of dots, organic electroluminescence display portions 12G, 12B and 12R including light-emitting layers which emit lights of respective colors.

An organic electroluminescence device of the present invention can be suitably used in a variety of fields such as computers, displays for use in vehicles, displays for outdoor use, domestic equipment, equipment for business use, electric household appliances, traffic-related displays, watch/clock displays, calendar displays, luminescent screens and acoustic equipment.

### EXAMPLES

The following explains Examples of the present invention. It should, however, be noted that the scope of the present invention is not confined to these Examples.

### Production Example 1

### Production of Top Emission Type Green Organic Electroluminescence Display Portion (Green Pixel Element) (1) (sm=2); Secondary Microcavity Structure Regarding Optical Length>

As a glass substrate, EAGLE 2000 (manufactured by Corning Incorporated) having a thickness of 0.7 mm and a refractive index of 1.5 was used.

Aluminum (Al) as an anode was deposited over the glass substrate by vacuum vapor deposition so as to have a thickness of 100 nm.

Next, 2-TNATA [4,4′,4″-tris(2-naphthylphenylamino)triphenylamine] and MnO₃, as a hole injection layer, were deposited at a proportion of 7:3 over the aluminum film by vacuum vapor deposition so as to have a thickness of 20 nm.

Next, 2-TNATA doped with 1.0% F4-TCNQ (2,3,5,6-tetrafluoro-7,7,8,8-tetracyanoquinodimethane), as a first hole transport layer, was deposited over the hole injection layer by vacuum vapor deposition so as to have a thickness of 141 nm.

Next, α-NPD [N,N′-(dinaphthylphenylamino)pyrene] as a second hole transport layer was deposited over the first hole transport layer by vacuum vapor deposition so as to have a thickness of 10 nm.

Next, a hole transport material A, represented by the structural formula below, as a third hole transport layer was deposited over the second hole transport layer by vacuum vapor deposition so as to have a thickness of 3 nm.

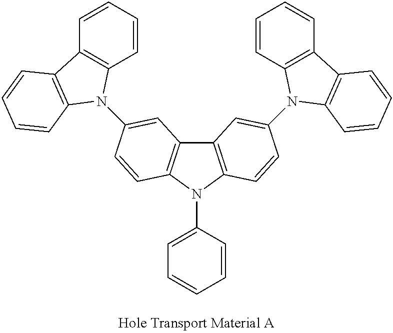

Next, a light-emitting layer, in which CBP (4,4′-dicarbazole-biphenyl) as a host material and a light-emitting material A (represented by the structural formula below) as a light-emitting material were contained at a proportion of 85:15, was deposited over the third hole transport layer by vacuum vapor deposition so as to have a thickness of 20 nm.

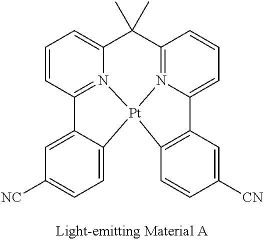

Next, BAlq (aluminum(III)bis(2-methyl-8-quinolinato)-4-phenylphenolate) as a first electron transport layer was deposited overt the light-emitting layer by vacuum vapor deposition so as to have a thickness of 39 nm.

Next, BCP (2,9-dimethyl-4,7-diphenyl-1,10-phenanthroline) as a second electron transport layer was deposited over the first electron transport layer by vacuum vapor deposition so as to have a thickness of 1 nm.

Next, LiF as a first electron injection layer was deposited over the second electron transport layer by vacuum vapor deposition so as to have a thickness of 1 nm.

Next, Al as a second electron injection layer was deposited over the first electron injection layer by vacuum vapor deposition so as to have a thickness of 1 nm.

Next, silver (Ag) as a cathode was deposited over the second electron injection layer by vacuum vapor deposition so as to have a thickness of 20 nm.

Next, SiON as a sealing layer was deposited over the cathode by CVD so as to have a thickness of 3,000 nm.

Next, an organic fluorine film (CYTOP, manufactured by ASAHI GLASS CO., LTD.) as an oil-repellent layer was deposited over the sealing layer by spin coating so as to have a thickness of 3,000 nm.

Next, SiO₂ as a lipophilic layer was deposited over the oil-repellent layer by sputtering so as to have a thickness of 100 nm.

In this manner, a green organic electroluminescence display portion (green pixel element) (1) was produced.

The green organic electroluminescence display portion (green pixel element) (1) had a secondary microcavity structure having an optical length L(λ) of 2λ (λ denotes an emission wavelength).

### Production Example 2

### Production of Top Emission Type Green Organic Electroluminescence Display Portion (Green Pixel Element) (2) (sm=3); Tertiary Microcavity Structure regarding Optical Length>

The same process as in the production of the green organic electroluminescence display portion (green pixel element) (1) in Production Example 1 was carried out except that the thickness of the first hole transport layer was changed from 141 nm to 271 nm. In this manner, a green organic electroluminescence display portion (green pixel element) (2) was produced.

The green organic electroluminescence display portion (green pixel element) (2) had a tertiary microcavity structure having an optical length L(λ) of 3λ (λ denotes an emission wavelength).

### Production Example 3

### Production of Top Emission Type Red Organic Electroluminescence Display Portion (Red Pixel Element) (sm=2); Secondary Microcavity Structure regarding Optical Length

As a glass substrate, EAGLE 2000 (manufactured by Corning Incorporated) having a thickness of 0.7 mm and a refractive index of approximately 1.5 was used.

Aluminum (Al) as an anode was deposited over the glass substrate by vacuum vapor deposition so as to have a thickness of 100 nm.

Next, 2-TNATA [4,4′,4″-tris(2-naphthylphenylamino)triphenylamine] and MnO₃, as a hole injection layer, were deposited at a proportion of 7:3 over the aluminum film by vacuum vapor deposition so as to have a thickness of 20 nm.

Next, 2-TNATA doped with 1.0% F4-TCNQ, as a first hole transport layer, was deposited over the hole injection layer by vacuum vapor deposition so as to have a thickness of 196 nm.

Next, α-NPD [N,N′-(dinaphthylphenylamino)pyrene] as a second hole transport layer was deposited over the first hole transport layer by vacuum vapor deposition so as to have a thickness of 10 nm.

Next, a light-emitting layer, obtained by mixing BAlq as a host material with a light-emitting material X (represented by the structural formula below) as a light-emitting material at a proportion of 95:5, was deposited over the second hole transport layer by vacuum co-deposition so as to have a thickness of 30 nm.

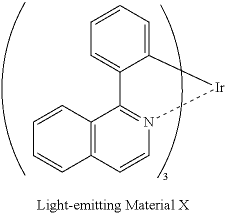

Next, BAlq as a first electron transport layer was deposited overt the light-emitting layer by vacuum vapor deposition so as to have a thickness of 48 nm.

Next, BCP as a second electron transport layer was deposited over the first electron transport layer by vacuum vapor deposition so as to have a thickness of 1 nm.

Next, LiF as a first electron injection layer was deposited over the second electron transport layer by vacuum vapor deposition so as to have a thickness of 1 nm.

Next, Al as a second electron injection layer was deposited over the first electron injection layer by vacuum vapor deposition so as to have a thickness of 1 nm.

Next, silver (Ag) as a cathode was deposited over the second electron injection layer by vacuum vapor deposition so as to have a thickness of 20 nm.

Next, SiON as a sealing layer was deposited over the cathode by CVD so as to have a thickness of 3,000 nm.

Next, an organic fluorine film (CYTOP, manufactured by ASAHI GLASS CO., LTD.) as an oil-repellent layer was deposited over the sealing layer by spin coating so as to have a thickness of 3,000 nm.

Next, SiO₂ as a lipophilic layer was deposited over the oil-repellent layer by sputtering so as to have a thickness of 100 nm.

In this manner, a red organic electroluminescence display portion (red pixel element) was produced.

The red organic electroluminescence display portion (red pixel element) had a secondary microcavity structure having an optical length L(λ) of 2λ (λ denotes an emission wavelength).

### Production Example 4

A top emission type blue organic electroluminescence display portion (blue pixel element) was produced.

<Production of Blue Organic Electroluminescence Display Portion (Blue Pixel Element) (sm=2); Secondary Microcavity Structure regarding Optical Length

As a glass substrate, EAGLE 2000 (manufactured by Corning Incorporated) having a thickness of 0.7 mm and a refractive index of approximately 1.5 was used.

Aluminum (Al) as an anode was deposited over the glass substrate by vacuum vapor deposition so as to have a thickness of 100 nm.

Next, 2-TNATA [4,4′,4″-tris(2-naphthylphenylamino)triphenylamine] and MnO₃, as a hole injection layer, were deposited at a proportion of 7:3 over the aluminum film by vacuum vapor deposition so as to have a thickness of 20 nm.

Next, 2-TNATA doped with 1.0% F4-TCNQ, as a first hole transport layer, was deposited over the hole injection layer by vacuum vapor deposition so as to have a thickness of 110 nm.

Next, α-NPD [N,N′-(dinaphthylphenylamino)pyrene] as a second hole transport layer was deposited over the first hole transport layer by vacuum vapor deposition so as to have a thickness of 10 nm.

Next, a hole transport material A, represented by the structural formula below, as a third hole transport layer was deposited over the second hole transport layer by vacuum vapor deposition so as to have a thickness of 3 nm.

Next, a light-emitting layer, obtained by mixing mCP (1,3-bis(carbazolyl)benzene) as a host material with a light-emitting material Y (represented by the structural formula below) as a light-emitting material at a proportion of 85:15, was deposited over the third hole transport layer by vacuum co-deposition so as to have a thickness of 30 nm.

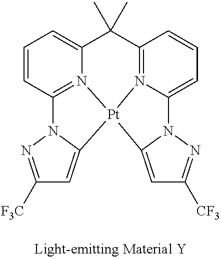

Next, BAlq as a first electron transport layer was deposited overt the light-emitting layer by vacuum vapor deposition so as to have a thickness of 29 nm.

Next, BCP as a second electron transport layer was deposited over the first electron transport layer by vacuum vapor deposition so as to have a thickness of 1 nm.

Next, LiF as a first electron injection layer was deposited over the second electron transport layer by vacuum vapor deposition so as to have a thickness of 1 nm.

Next, Al as a second electron injection layer was deposited over the first electron injection layer by vacuum vapor deposition so as to have a thickness of 1 nm.

Next, silver (Ag) as a cathode was deposited over the second electron injection layer by vacuum vapor deposition so as to have a thickness of 20 nm.

Next, SiON as a sealing layer was deposited over the cathode by CVD so as to have a thickness of 3,000 nm.

Next, an organic fluorine film (CYTOP, manufactured by ASAHI GLASS CO., LTD.) as an oil-repellent layer was deposited over the sealing layer by spin coating so as to have a thickness of 3,000 nm.

Next, SiO₂ as a lipophilic layer was deposited over the oil-repellent layer by sputtering so as to have a thickness of 100 nm.

In this manner, a blue organic electroluminescence display portion (blue pixel element) was produced.

The blue organic electroluminescence display portion (blue pixel element) had a secondary microcavity structure having an optical length L(λ) of 2λ (λ denotes an emission wavelength).

A cylinder lens (product name: REFRACTIVE LIQUID KPR, manufactured by SHIMADZU CORPORATION) having a radius of 10 mm and a refractive index of 1.8 was installed in each of the organic electroluminescence display portions produced in Production Examples 1 to 4, using matching oil (refractive index: approximately 1.8). The luminous intensity distributions of the organic electroluminescence display portions were measured as described below. By evaluating the luminous intensity distributions, it is possible to understand an angular distribution of light in glass.

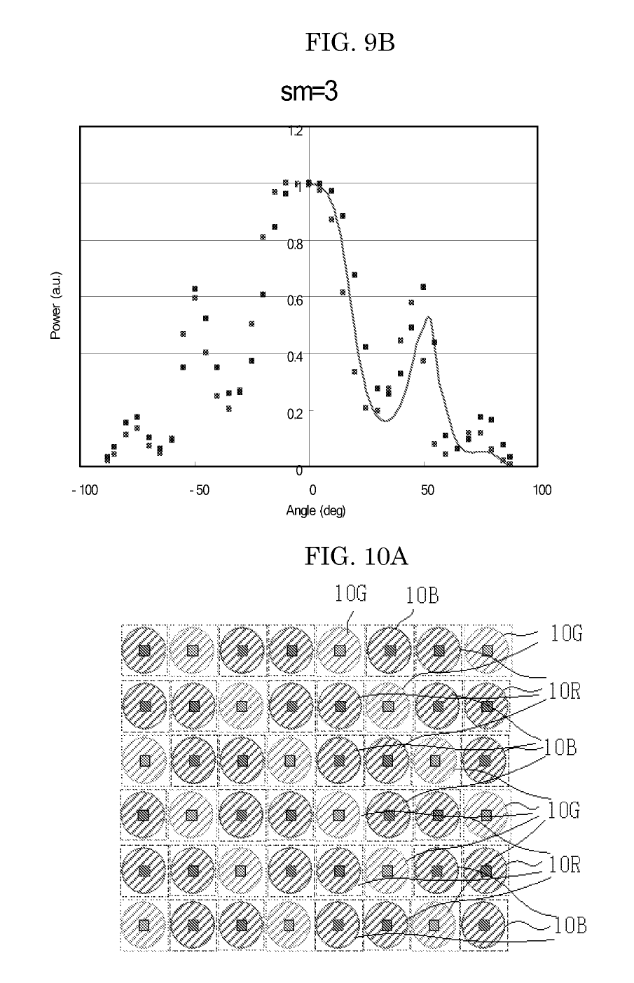

The result of the luminous intensity distribution regarding the green organic electroluminescence display portion (green pixel element) (1) is shown in FIG. 9A, and the result of the luminous intensity distribution regarding the green organic electroluminescence display portion (green pixel element) (2) is shown in FIG. 9B.

### <Method of Measuring Luminous Intensity Distribution>

A silicon detector was attached to a goniometer, each organic electroluminescence display portion was made to emit light, then the relationship between an angle indicated by the goniometer and a voltage signal corresponding to the light intensity indicated by the silicon detector was measured, and the luminous intensity distribution was thus calculated.

### Example 1

### A Case where the Color of One Colored Lens Differed from the Colors of all Colored Lenses that were Adjacent to the One Colored Lens

Using the green organic electroluminescence display portion produced in Production Example 1, the red organic electroluminescence display portion produced in Production Example 3, and the blue organic electroluminescence display portion produced in Production Example 4, an organic electroluminescence device in which the organic electroluminescence display portions (lenses) of each color were aligned as shown in FIG. 1A was produced in accordance with the production method below.

### <Production Method of Organic Electroluminescence Device>

The light-emitting elements (organic electroluminescence display portions) were arranged so as to constitute a structure of an organic EL display, then an SiON film as a sealing layer was deposited by sputtering so as to have a thickness of 3 μm, and subsequently CYTOP CTL-107 (manufactured by ASAHI GLASS CO., LTD.) was deposited by dip coating so as to have a thickness of 1 μm. Thereafter, at portions where lenses were to be formed, SiO₂ films were deposited by mask sputtering so as to have a thickness of 100 nm each. RGB inks were applied to respective pixels, using DMP-2831 (manufactured by FUJIFILM Corporation) as an inkjet apparatus.

### Example 2

### A Case where the Color of One Colored Lens Differed from the Colors of all Colored Lenses that were Adjacent to the One Colored Lens

An organic electroluminescence device was produced in the same manner as in Example 1 except that the green organic electroluminescence display portion produced in Production Example 2 was used instead of the green organic electroluminescence display portion produced in Production Example 1.

### Example 3

### A Case where the Color of One Colored Lens Differed from the Colors of Four Colored Lenses Aligned in Two Directions among Colored Lenses that were Adjacent to the One Colored Lens

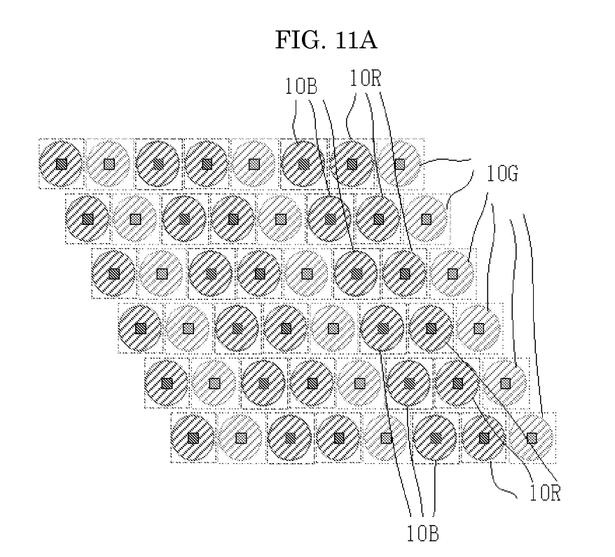

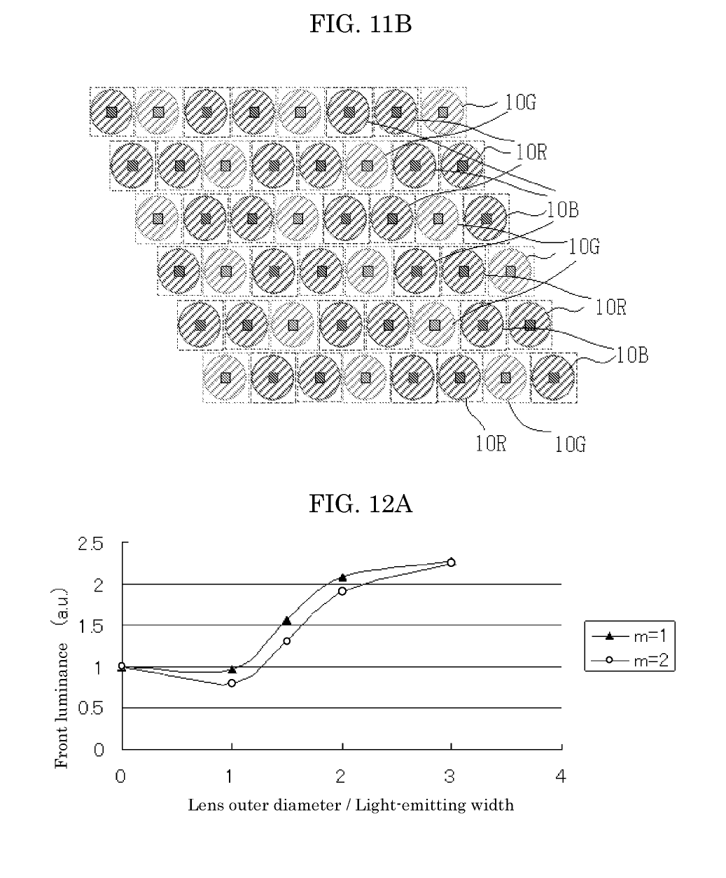

An organic electroluminescence device was produced in the same manner as in Example 1 except that the organic electroluminescence display portions (lenses) of each color were aligned as shown in FIG. 11A.

### Example 4

### A Case where the Color of One Colored Lens Differed from the Colors of Six Colored Lenses Aligned in Three Directions among Colored Lenses that were Adjacent to the One Colored Lens

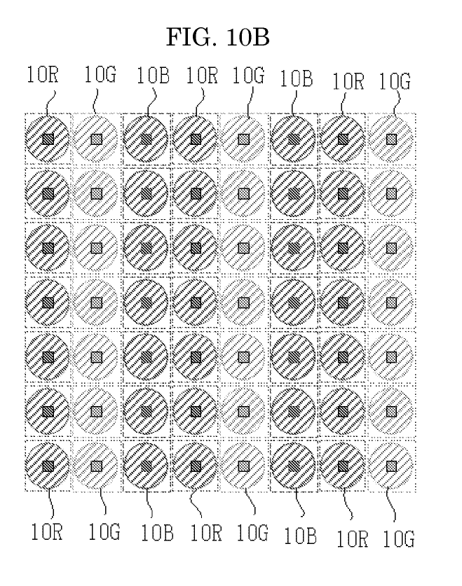

An organic electroluminescence device was produced in the same manner as in Example 1 except that the organic electroluminescence display portions (lenses) of each color were aligned as shown in FIG. 10A.

### Example 5

### A Case where the Color of one Colored Lens Differed from the Colors of Six Colored Lenses Aligned in Three Directions among Colored Lenses that were Adjacent to the One Colored Lens

An organic electroluminescence device was produced in the same manner as in Example 1 except that the organic electroluminescence display portions (lenses) of each color were aligned (color lenses of the same color were aligned along vertical lines) as shown in FIG. 10B.

### Example 6

### A Case where the Color of One Colored Lens Differed from the Colors of all Colored Lenses that were Adjacent to the One Colored Lens

An organic electroluminescence device was produced in the same manner as in Example 1 except that the organic electroluminescence display portions (lenses) of each color were aligned as shown in FIG. 11B.

### Example 7

### A Case where Colored Lenses were Aligned as Shown in FIG. 7

An organic electroluminescence device was produced in the same manner as in Example 1 except that the organic electroluminescence display portions (lenses) of each color were aligned as shown in FIG. 7.

### Example 8

### A Case where Colored Lenses were Aligned as Shown in FIG. 8

An organic electroluminescence device was produced in the same manner as in Example 1 except that the organic electroluminescence display portions (lenses) of each color were aligned as shown in FIG. 8.

### Example 9

### A Case where Color Filters, which were Formed at Interfaces of Lenses on the Side of Light-Emitting Layers, were used

An organic electroluminescence device was produced in the same manner as in Example 1 except that it was produced in accordance with the production method below, using color filters which were formed at interfaces of lenses on the side of light-emitting layers, instead of using the colored lenses.

### <Production Method of Organic Electroluminescence Device>

A structure of an organic EL display was produced, then an SiON film as a sealing layer was deposited by sputtering so as to have a thickness of 3 μm, and subsequently CYTOP CTL-107 (manufactured by ASAHI GLASS CO., LTD.) was deposited by dip coating so as to have a thickness of 1 μm. Thereafter, at portions where lenses were to be formed, SiO₂ films were deposited by mask sputtering so as to have a thickness of 100 nm each. RGB inks were applied to respective pixels, using DMP-2831 (manufactured by FUJIFILM Corporation) as an inkjet apparatus, and color filters were thus produced. After that, a transparent UV ink was applied using the inkjet apparatus so as to form lenses.

### Example 10

### A Case where Color Filters, which were Formed so as to Cover the Surfaces of Lenses, were used

An organic electroluminescence device was produced in the same manner as in Example 1 except that it was produced in accordance with the production method below, using color filters which were formed so as to cover the surfaces of lenses, instead of using the colored lenses.

### <Production Method of Organic Electroluminescence Device>

A structure of an organic EL display was produced, then an SiON film as a sealing layer was deposited by sputtering so as to have a thickness of 3 μm, and subsequently CYTOP CTL-107 (manufactured by ASAHI GLASS CO., LTD.) was deposited by dip coating so as to have a thickness of 1 μm. Thereafter, at portions where lenses were to be formed, SiO₂ films were deposited by mask sputtering so as to have a thickness of 100 nm each. A transparent UV ink was applied to each pixel separately, using DMP-2831 (manufactured by FUJIFILM Corporation) as an inkjet apparatus, and transparent lenses were thus produced. After that, RGB inks were separately applied to the respective lenses so as to form color filters on the surfaces of the lenses.

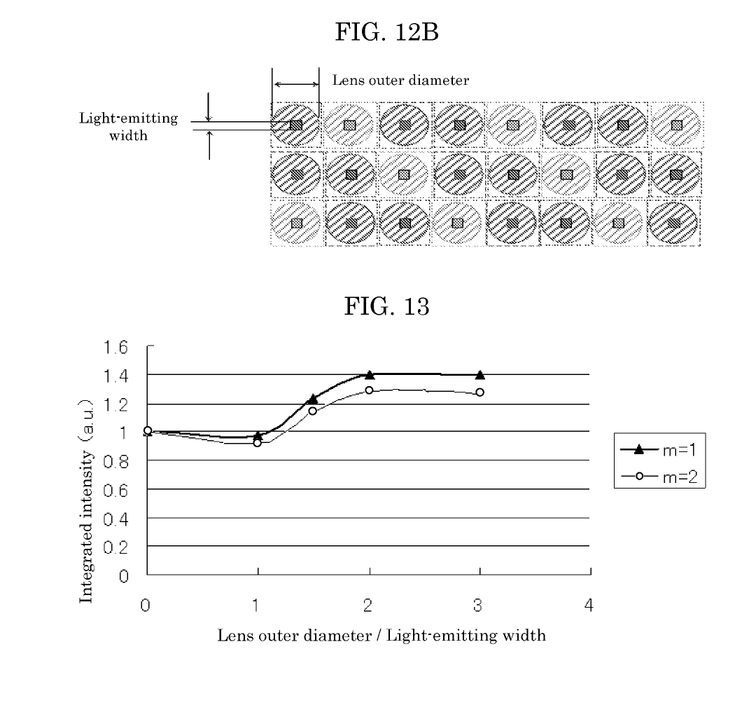

Regarding each of the organic electroluminescence devices produced, the light extraction efficiency and the image blurring were measured as described below. To determine the light extraction efficiency, both the integrated intensity and the front luminance were measured. The results are shown in FIG. 12A (front luminance) and FIG. 13 (integrated intensity).

### <Measurement of Light Extraction Efficiency>

The integrated intensity and the front luminance of an organic electroluminescence element with lenses were respectively divided by the integrated intensity and the front luminance of the organic electroluminescence element without the lenses. Each of the obtained values was defined as the light extraction efficiency.

Parenthetically, the integrated intensity was measured using an integrating sphere, and the front luminance was measured using a spectral radiance meter (SR-3, manufactured by TOPCON CORPORATION). An element with the ratio of the lens outer diameter to the light-emitting width (FIG. 12B) being 3 was evaluated.

### <Measurement of Image Blurring>

To measure the image blurring, a luminance chromaticity uniformity measuring apparatus (UA-1000, manufactured by TOPCON CORPORATION) was used. In the case where one pixel was made to emit light, the image blurring was evaluated as C when the maximum value of the ratio of the luminescence intensity of an adjacent pixel to the luminescence intensity of the one pixel (luminescence intensity of adjacent pixel/luminescence intensity of one pixel) was greater than 1/1,000, the image blurring was evaluated as B when the maximum value was in the range of 1/10,000 to 1/10,000, and the image blurring was evaluated as A when the maximum value was less than 1/10,000. An element with the ratio of the lens outer diameter to the light-emitting width being 3 was evaluated. For example, regarding FIGS. 7 and 8, evaluations were carried out regarding a section of the same color, surrounding six light-emitting portions and six lenses, as a pixel.

TABLE 1

| | Light | Light | | |
|---|---|---|---|---|
| | extraction | extraction | | |
| | efficiency | efficiency | | Ratio of |
| | (Front | (Integrated | Image | luminescence |
| Example | luminance) | intensity) | blurring | intensity |
| 1 | 2.3 times | 1.3 to 1.4 | A | Less than |
| | | times | | 1/10,000 |
| | | | | (less than |
| | | | | measurement |
| | | | | limit) |
| 2 | 2.3 times | 1.3 to 1.4 | A | Less than |
| | | times | | 1/10,000 |
| | | | | (less than |
| | | | | measurement |
| | | | | limit) |
| 3 | 2.3 times | 1.3 to 1.4 | B | 1/5,000 |
| | | times | | |
| 4 | 2.3 times | 1.3 to 1.4 | B | 1/5,000 |
| | | times | | |
| 5 | 2.3 times | 1.3 to 1.4 | B | 1/5,000 |
| | | times | | |
| 6 | 2.3 times | 1.3 to 1.4 | A | Less than |
| | | times | | 1/10,000 |
| | | | | (less than |
| | | | | measurement |
| | | | | limit) |
| 7 | 2.3 times | 1.3 to 1.4 | B | 1/5,000 |
| | | times | | |
| 8 | 2.3 times | 1.3 to 1.4 | A | Less than |
| | | times | | 1/10,000 |
| | | | | (less than |
| | | | | measurement |
| | | | | limit) |
| 9 | 2.3 times | 1.3 to 1.4 | B | 1/5,000 |
| | | times | | |
| | | | | Less than |
| 10 | 2.3 times | 1.3 to 1.4 | A | 1/10,000 |
| | | times | | (less than |
| | | | | measurement |
| | | | | limit) |
| Conventional | 2.3 times | 1.3 to 1.4 | C | 1/500 |
| | | times | | |

Since an organic electroluminescence device of the present invention causes less image bleeding, it can be suitably used both as a bottom emission type organic electroluminescence device and as a top emission type organic electroluminescence device. For example, it can be suitably used in a variety of fields such as computers, displays for use in vehicles, displays for outdoor use, domestic equipment, equipment for business use, electric household appliances, traffic-related displays, watch/clock displays, calendar displays, luminescent screens and acoustic equipment.

What is claimed is:

1. An organic electroluminescence device comprising:
a plurality of organic electroluminescence display portions, each of which includes at least an anode, a light-emitting layer and a cathode;
a plurality of lenses which are placed over the organic electroluminescence display portions, and each of which controls an optical path of light emitted from the light-emitting layer; and
a plurality of filter layers, each of which is formed integrally with each lens and placed so as to cover the optical path in each lens, and transmits the light emitted from the light-emitting layer,
wherein the filter layer formed integrally with one lens among the lenses absorbs at least light with a peak wavelength among light which has passed through at least one of lenses that are adjacent to the one lens.

2. The organic electroluminescence device according to claim 1, wherein the filter layer formed integrally with the one lens among the lenses absorbs at least lights with peak wavelengths among lights which have passed through lenses aligned in at least two directions among the lenses that are adjacent to the one lens.

3. The organic electroluminescence device according to claim 2, wherein the filter layer formed integrally with the one lens among the lenses absorbs at least lights with peak wavelengths among lights which have passed through lenses aligned in at least three directions among the lenses that are adjacent to the one lens.

4. The organic electroluminescence device according to claim 1, wherein the filter layer formed integrally with the one lens among the lenses absorbs at least lights with peak wavelengths among lights which have passed through all the lenses that are adjacent to the one lens.

5. The organic electroluminescence device according to claim 1, wherein the one lens functions as the filter layer.

6. The organic electroluminescence device according to claim 1, wherein each filter layer is formed at an interface of each lens on the side of the light-emitting layer.

7. The organic electroluminescence device according to claim 1, wherein each filter layer is formed so as to cover a surface of each lens.

8. The organic electroluminescence device according to claim 1, further comprising a plurality of pixel elements each having a plurality of the organic electroluminescence display portions including the light-emitting layers which emit light of the same color,
wherein the light-emitting layers of the organic electroluminescence display portions in one pixel element among the pixel elements emit light whose color is different from the color of light emitted by the light-emitting layers of the organic electroluminescence display portions in at least one of pixel elements that are adjacent to the one pixel element.

9. The organic electroluminescence device according to claim 8, wherein the light-emitting layers of the organic electroluminescence display portions in the one pixel element among the pixel elements emit light whose color is different from the colors of lights emitted by the light-emitting layers of the organic electroluminescence display portions in the pixel elements that are adjacent to the one pixel element.

10. A method for producing an organic electroluminescence device, comprising:
forming a plurality of filter layers by an inkjet method,
wherein the organic electroluminescence device comprises:
a plurality of organic electroluminescence display portions, each of which includes at least an anode, a light-emitting layer and a cathode;
a plurality of lenses which are placed over the organic electroluminescence display portions, and each of which controls an optical path of light emitted from the light-emitting layer; and
the plurality of filter layers, each of which is formed integrally with each lens and placed so as to cover the optical path in each lens, and transmits the light emitted from the light-emitting layer, and
wherein the filter layer formed integrally with one lens among the lenses absorbs at least light with a peak wavelength among light which has passed through at least one of lenses that are adjacent to the one lens.

11. The method according to claim 10, wherein the filter layer formed integrally with the one lens among the lenses absorbs at least lights with peak wavelengths among lights which have passed through lenses aligned in at least two directions among the lenses that are adjacent to the one lens.

12. The method according to claim 11, wherein the filter layer formed integrally with the one lens among the lenses absorbs at least lights with peak wavelengths among lights which have passed through lenses aligned in at least three directions among the lenses that are adjacent to the one lens.

13. The method according to claim 10, wherein the filter layer formed integrally with the one lens among the lenses absorbs at least lights with peak wavelengths among lights which have passed through all the lenses that are adjacent to the one lens.

14. The method according to claim 10, wherein the one lens functions as the filter layer.

15. The method according to claim 10, wherein each filter layer is formed at an interface of each lens on the side of the light-emitting layer.

16. The method according to claim 10, wherein each filter layer is formed so as to cover a surface of each lens.

17. The method according to claim 10, wherein the organic electroluminescence device further comprises a plurality of pixel elements each having a plurality of the organic electroluminescence display portions including the light-emitting layers which emit light of the same color, and
wherein the light-emitting layers of the organic electroluminescence display portions in one pixel element among the pixel elements emit light whose color is different from the color of light emitted by the light-emitting layers of the organic electroluminescence display portions in at least one of pixel elements that are adjacent to the one pixel element.

18. The method according to claim 17, wherein the light-emitting layers of the organic electroluminescence display portions in the one pixel element among the pixel elements emit light whose color is different from the colors of lights emitted by the light-emitting layers of the organic electroluminescence display portions in the pixel elements that are adjacent to the one pixel element.
